(19) United States
(12) Patent Application Publication
(10) Pub. No.: US 2008/0072953 A1
(43) Pub. Date: Mar. 27, 2008

(54) Back contact device for photovoltaic cells and method of manufacturing a back contact device

(75) Inventors: Jason M. Stephens, Goleta, CA (US); Kevin Michael Coakley, Andover, MA (US); Guleid Hussen, Goleta, CA (US)

Correspondence Address: GREENSFELDER HEMKER & GALE PC, SUITE 2000, 10 SOUTH BROADWAY, ST LOUIS, MO, 63102, US

(73) Assignee: ThinSilicon Corp., Goleta, CA (US)

(21) Appl. No.: 11/903,787

(22) Filed: Sep. 25, 2007

Related U.S. Application Data
(60) Provisional application No. 60/932,374, filed on May 31, 2007.
(60) Provisional application No. 60/932,389, filed on May 31, 2007.
(60) Provisional application No. 60/932,395, filed on May 31, 2007.
(60) Provisional application No. 60/847,475, filed on Sep. 27, 2006.

(51) Int. Cl. H01L 31/042

(52) U.S. Cl. 136/249; 136/251; 136/256; 136/258

(57) ABSTRACT

One or more embodiments of the presently described invention provide a method for fabricating an all-back contact photovoltaic cell. The method includes the steps of depositing a semiconductor layer on a non-opaque substrate, increasing a level of crystallinity of the semiconductor layer by exposing it to a focused beam of energy, doping the semiconductor layer with first and second dopants on one side to create at least two doped regions, and providing electrical contacts to the doped regions by depositing a conductive layer on the semiconductor layer so that the electrical contacts are on the same side of the semiconductor layer while incident light strikes the layer from an opposing side.

### CROSS-REFERENCE TO RELATED APPLICATIONS

This application is a nonprovisional utility application that claims priority benefit of copending U.S. Provisional Patent application Ser. Nos. 60/932,374 (the “'374 application”), 60/932,389 (the “'389 application”), 60/932,395 (the “'395 application”) and 60/847,475 (the “'475 application). The '374 application was filed on May 31, 2007, and is entitled “Method of Annealing a Large Area Semiconductor Film Using Electron Beams.” The '389 application was filed on May 31, 2007, and is entitled “Method of Producing a Microcrystalline Silicon Film for Photovoltaic Cells.” The '395 application was filed on May 31, 2007, and is entitled “Method of Producing a Photovoltaic Module.” The '475 application was filed on Sep. 27, 2006, and is entitled “Back Contact Device for Photovoltaic Cells.” The entire disclosures of the '375, '389, '395 and '475 applications are incorporated by reference herein in their entirety.

### BACKGROUND OF THE INVENTION

The presently described technology generally relates to photovoltaic (“PV”) cells. More particularly, the presently described technology relates to a back contact device for photovoltaic cells made from recrystallized semiconductor films on non-opaque, or transparent or translucent carrier substrates.

One key factor contributing to the lack of widespread usage of PV cells as a source of electricity is the cost of producing the cells and PV modules. For example, current PV cells are manufactured using electronic-grade semiconductor wafers, such as silicon wafers. These wafers must be substantially free of impurities. These wafers also typically are produced with a thickness in the range 150-300 microns (“μm”), or 150×10⁻⁶ to 300×10⁻⁶ meters (“m”), in order to provide increased mechanical and thermal stability and to allow the wafers to be handled without breaking. Producing or purchasing such high purity wafers adds significant expense to the process of manufacturing PV cells and modules.

Additionally, the required thickness of semiconductor materials for absorbing a large fraction of incident light and producing efficient PV cells generally is in the range of 1 to 100 μm, or 1×10⁻⁶ to 100×10⁻⁶ m. As the thickness of semiconductor materials in PV cells increases above this range, the extra semiconductor material contributes only marginally to light absorption in the PV cell, so the cell efficiency does not increase substantially. Therefore, while semiconductor wafers must usually be made 150 to 300 μm, or 150×10⁻⁶ to 300×10⁻⁶ m, thick for mechanical handling purposes, a significant fraction of the thickness of the wafer can be effectively useless from the standpoint of increasing the efficiency of the cell.

Thus, one opportunity for a significant reduction in the cost of producing efficient PV cells is to produce cells in which a thinner semiconductor material is deposited on a low-cost carrier substrate. The cost of producing a thin semiconductor film on a low-cost carrier substrate typically is significantly less than manufacturing or obtaining an electronic-grade semiconductor wafer. In addition, the cost of producing a thin semiconductor film of high purity can be significantly less than the cost of producing or purchasing a thicker semiconductor wafer of the same purity level. If the thin semiconductor film absorbs incident light as effectively as a wafer-based PV cell, the use of a thin semiconductor film can approach or meet the efficiency of a wafer-based PV cell while lowering the cost of manufacturing the cell.

While the use of a thin semiconductor film instead of an electronic-grade semiconductor wafer can lower the cost of a PV cell while maintaining the same efficiency, an additional challenge is the deposition of the semiconductor film. In general, a crystalline or polycrystalline semiconductor material is desirable for an efficient PV cell. In order to produce a crystalline or polycrystalline thin semiconductor film, expensive and time-consuming deposition techniques must be used. For example, polycrystalline silicon films can be grown directly in plasma-enhanced chemical vapor deposition (“PECVD”) systems, but the deposition rate generally must be kept below 50 nm/min, or 50×10⁻⁹ m/min, in order to produce films with sufficient electronic quality. Since such films are generally made to be 1 to 5 μm, or 1×10⁻⁶ to 5×10⁻⁶ m, thick in order to absorb a significant fraction of the incident light, very long deposition times are required to deposit the films. For example, deposition times on the order of 20 to 100 minutes can be required.

These long deposition times necessitate the use of several capital-intensive PECVD systems in a production facility or factory in order to obtain a reasonably high overall throughput. In addition, the polysilicon PECVD technique usually yields very little control over the film morphology and grain size, with a typical grain size in the 1 to 50 nm, or 1×10⁻⁹ to 50×10⁻⁹ m, range.

In accordance with at least one embodiment of the presently described invention, one way to reduce the cost and time required for producing a high-quality crystalline or polycrystalline semiconductor material is to deposit the semiconductor material in an amorphous (that is, non-crystalline) or microcrystalline state and then later increase the crystallinity of the material. This can allow the deposition rate to be increased without regard for the electronic properties of the material, which are generally of too low of quality to produce highly efficient, stable PV cells when the deposition rate is high.

In order to produce higher quality crystalline films for a more efficient PV cell or module, the films then can be heated to high temperatures and allowed to cool. However, typically the processing temperature for crystallizing the films is often outside the temperature range that can be withstood for a long duration of time by low-cost carrier substrates because the temperature can exceed the softening point of the substrates. For example, the processing temperature can be around 750 to 2000° C. Most low-cost carrier substrates such as borosilicate glass and float glass cannot withstand temperatures above 750° C. for a long enough duration to crystallize most semiconductor films. Therefore, it is desirable to find a way to deposit an amorphous or low-quality semiconductor film (and thus reduce the cost and time required for manufacturing a PV cell) on a low-cost carrier substrate (also reducing the required cost) and then heat the film to increase its crystallinity while not damaging the substrate. In other words, it is desirable to develop a way to process the semiconductor films so that sufficient heat is imparted to the semiconductor film for it to crystallize or be activated while minimizing the heat exposure to the underlying substrate.

One method used to crystallize semiconductor layers is zone melt recrystallization (“ZMR”). ZMR typically involves selectively heating a narrow lateral region of semiconductor film and sweeping this heated region across the entire substrate (referred to as a “ZMR sweep”). Techniques for selectively heating a narrow region of semiconductor material include the use of a directed or focused beam of energy such as laser beams, electron beams (“e-beams”), and line-shaped, focused incandescent lamps, for example, although other techniques can be used.

In general, the input power in ZMR processing is high enough to melt the semiconductor layer (which crystallizes or increases its crystallinity upon solidification). However, with ZMR processing, device layers in contact with the heated semiconductor film (such as metallic electrodes) can reach extremely high temperatures (1000-2000° C., for example) during a ZMR sweep. These temperatures can be above the maximum temperature that can be withstood by most low cost substrates, intermediate metal layers and/or the doped regions within the semiconductor material itself. Thus, making electrical contact to semiconductor films that are crystallized (or at least have their crystallinity increased) using ZMR remains a challenge.

Once a high-quality semiconductor layer has been produced (using either traditional wafer-growth methods or ZMR of a semiconductor film on a substrate), subsequent semiconductor processing steps such as doping and positive and negative metal electrode deposition typically are used to produce a working PV device. In silicon wafer-based devices, it is possible to fabricate PV cells by doping both the front and back sides of the wafer uniformly, and then depositing the positive and negative metal electrodes on the two sides separately (the “conventional” design). Alternatively, the dopants and positive and negative electrodes can be selectively deposited only on one side of the wafer so that both the positive and negative charge carriers are collected on the same side of the device (the “all-back contact” design).

However, in order for PV cells with all-back contacts to function efficiently, the minority carrier diffusion length in the semiconductor must be several times larger than its thickness in order to ensure that a large fraction of the photogenerated carriers reach their respective electrodes. Achieving a minority carrier diffusion length in the range 500 μm to 1 millimeter (“mm”), or 500×10⁻⁶ to 1×10⁻³ m (as can be necessary in the case of thick, wafer-based cells) requires very pure and nearly structurally perfect silicon, resulting in a significant increase in the cost of the wafers. Conversely, in accordance with one or more embodiments of the presently described invention, the required carrier diffusion length for thin films of crystalline semiconductors is less because the films are thinner than the wafers, thereby permitting the purity and crystallinity requirements of the films to be relaxed when compared to the same of wafers.

In addition, in existing all-back contact designs, an opaque ceramic substrate is used due to the extremely high temperatures that are used in the processing of the semiconductor material. Thus, existing all-back contact PV cells have all electrical contacts to the semiconductor material on the same side that incident light strikes the semiconductor material. As a result, a significant portion of the side of PV cells and modules that incident light strikes is prevented from striking the semiconductor material. Thus, there is a smaller area for incident light to strike the semiconductor material and the efficiency of these designs decreases.

Therefore, a need exists for PV cells that use less semiconductor material in order to reduce manufacturing costs. In addition, a need exists for PV cells with less stringent purity and processing requirements for the semiconductor layer of the cells, while approaching or meeting the efficiency of wafer-based PV cells. Finally, a need exists for PV cells to be produced in such a way as to prevent damage to semiconductor and electrode layers during ZMR, and for the layers to be placed adjacent to, or on top of less expensive, non-opaque (or translucent or transparent) carrier substrate. One or more embodiments of the presently described invention meet these and other needs in the art.

An additional problem with existing methods of manufacturing PV cells and with existing ZMR techniques is the speed at which the semiconductor films are crystallized or have their level of crystallinity increased. For example, in crystallizing semiconductor films using e-beams, existing e-beam systems cannot uniformly cover or expose a large-area substrate, such as a substrate that is greater than 1 m².

In addition, while large-area scanning methods have been devised in electron beam curing systems, this has not yet been accomplished in systems involving highly focused line-source e-beams in a vacuum environment. This presents a problem as it can be advantageous to use a focused line-source electron beam for crystallizing or thermally treating semiconductor films because the linear beam emission profile allows films to be scanned primarily in one direction, and because the focusing of the beam allows the film to be heated very effectively. Thus, a need exists for developing a method for scanning a large-area substrate with a semiconductor film with e-beams using line-source e-beams.

While existing methods can generate a small-length focused line-source e-beam for processing semiconductor films, the length of the e-beam line is limited. For example, some existing methods can only produce e-beam lines with lengths on the order of 2 to 10 centimeters (“cm”). One example of such a method is the Pierce reflector system in which biased conducting plates, or reflectors, are used to focus an e-beam line emitted by a filament. However, the length of the emitted e-beam line is limited. That is, it is unlikely that the line length can be extended indefinitely with a single filament. As the length of the filament wire in the e-beam source increases in order to increase the length of the e-beam line, the applied voltage necessary to heat the filament to facilitate thermionic emission also increases, thereby causing the focus of the e-beam line to change with position. This change in focus may be partially compensated for by adjusting the position of the filament gradually along its length. However, the position of the filament is very difficult to control over increasing distances because the position of the filament must be accurate to within a fraction of a millimeter over its length. Thus, adjusting the position of the filament can be an impractical solution for beam lengths above 10 cm. For this reason, existing line e-beam systems can be fixed to line lengths at 10 cm or less.

In addition, it can be very difficult to maintain the precise geometry of a Pierce reflector system over the width of a large-area substrate, which may be as wide as 2 to 3 m across. These factors make it very difficult (if not impossible) to obtain a uniform crystallization pattern over large-area substrates using a line e-beam generated from a single filament.

As an alternative to using a line-source electron beam to crystallize a semiconductor film, a point-source beam may also be used by sweeping rapidly in one direction while scanning in the other direction, similar to the way that an electron beam is rastered inside a cathode ray tube. However, the substrate area that can be covered using a point source e-beam in existing systems and methods is also limited, as evidenced by the very large aspect ratios, undesirable screen curvature, and limited screen size of state-of-the-art cathode ray tubes.

Thus, a need also exists for an improved method and system for uniformly exposing a large-area substrate to e-beams. Such a method can provide for more uniform and improved crystallization of semiconductor films on the substrate in a faster time than existing methods. One or more embodiments of the presently described invention meet this and other needs in the art.

### BRIEF SUMMARY OF THE INVENTION

One or more embodiments of the presently described invention provides a method for fabricating an all-back contact photovoltaic cell. The method includes the steps of depositing a semiconductor layer on a non-opaque substrate, increasing a level of crystallinity of the semiconductor layer by exposing it to a focused beam of energy, doping the semiconductor layer with first and second dopants on one side to create at least two doped regions, and providing electrical contacts to the doped regions by depositing a conductive layer on the semiconductor layer so that the electrical contacts are on the same side of the semiconductor layer while incident light strikes the layer from an opposing side.

Additionally, one or more embodiments of the presently described invention provides an all-back contact thin film photovoltaic cell. The cell comprises a non-opaque substrate, a semiconductor layer, a capping layer and a conductive layer. The semiconductor layer is deposited in at least one of an amorphous and microcrystalline state. A level of crystallinity of the semiconductor layer is increased by exposing the layer to one or more focused beams of energy. The capping layer is deposited adjacent to the semiconductor layer and is etched twice. Once to expose a first set of areas of the semiconductor layer and a second time to expose a second set of areas of the semiconductor layer. The first set of areas is doped with a first type of dopant and the second set of areas is doped with a second type of dopant. The conductive layer is deposited on a first side of the semiconductor layer opposite the substrate to provide electrical contacts with the first and second areas. In operation, incident light passes through the substrate and strikes the semiconductor layer on a side that is opposite the first side, or the side that includes the first and second areas and the electrical contacts.

Additionally, one or more embodiments of the presently described invention provides a method for fabricating an all-back contact photovoltaic module. The method includes the steps of providing a semiconductor layer and a non-opaque substrate on a first side of the module, increasing a level of crystallinity of the semiconductor layer by exposing it to one or more focused beams of energy, doping the semiconductor layer in each of a plurality of adjacent photovoltaic cells in the module with a first dopant in a first set of volumes in each of the cells, doping the semiconductor layer with a second dopant in a second set of volumes in each of the cells, removing one or more portions of the semiconductor layer to define at least one gap between adjacent photovoltaic cells, depositing an insulating material in the gap, depositing a conductive material on the semiconductor layer at each of the first and second sets of volumes of each cell and on the insulating material, and etching the conductive material to create electrical contacts (a) to the first set of volumes for each of the cells, (b) to the second set of volumes for each of the cells and (c) between the first set of volumes in one of the cells and the second set of volumes in another one of the cells. The electrical contacts are located on a second side of the module that is opposite the first side. Light that is incident to the module strikes the semiconductor layer in each of the cells through the first side.

Additionally, one or more embodiments of the presently described invention provides an all-back contact photovoltaic module. The module includes a plurality of photovoltaic cells, an insulating material, and a conductive material. Each of the photovoltaic cells includes a semiconductor layer and a non-opaque substrate on a first side of the module. Each of the semiconductor layers includes a first set of volumes doped with a first dopant and a second set of volumes doped with a second dopant. A level of crystallinity of each of the semiconductor layers is increased by exposing the layers to one or more focused beams of energy. The insulating material is located in a gap between adjacent photovoltaic cells and is created by removing one or more portions of the semiconductor layer between adjacent cells in the module. The conductive material is deposited adjacent to the first set of volumes and the second set of volumes for each of the cells and adjacent to the insulating material. The conductive material is then etched to create electrical contacts (a) to the first set of volumes for each of the cells, (b) to the second set of volumes for each of the cells and (c) between the first set of volumes in one of the cells and said second set of volumes in another one of the cells. The electrical contacts are on a second side of the module that is opposite the first side. Light that is incident to the module passes through the substrate and strikes the semiconductor layers on the first side.

### BRIEF DESCRIPTION OF THE SEVERAL VIEWS OF THE DRAWINGS

FIG. 1 illustrates a cross-sectional view of an all-back contact thin film PV cell at one step in a method of fabricating the cell in accordance with an embodiment of the presently described invention.

FIG. 2 illustrates a cross-sectional view of the all-back contact thin film PV cell at another step in a method of fabricating the cell in accordance with an embodiment of the presently described invention.

FIG. 3 illustrates a cross-sectional view of the all-back contact thin film PV cell at another step in a method of fabricating the cell in accordance with an embodiment of the presently described invention.

FIG. 4 illustrates a cross-sectional view of the all-back contact thin film PV cell at another step in a method of fabricating the cell in accordance with an embodiment of the presently described invention.

FIG. 5 illustrates a cross-sectional view of the all-back contact thin film PV cell at another step in a method of fabricating the cell in accordance with an embodiment of the presently described invention.

FIG. 6 illustrates a cross-sectional view of the all-back contact thin film PV cell at another step in a method of fabricating the cell in accordance with an embodiment of the presently described invention.

FIG. 7 illustrates a cross-sectional view of the all-back contact thin film PV cell at another step in a method of fabricating the cell in accordance with an embodiment of the presently described invention.

FIG. 8 illustrates a cross-sectional view of the all-back contact thin film PV cell at another step in a method of fabricating the cell in accordance with an embodiment of the presently described invention.

FIG. 9 illustrates a cross-sectional view of the all-back contact thin film PV cell at another step in a method of fabricating the cell in accordance with an embodiment of the presently described invention.

FIG. 10 illustrates a cross-sectional view of the all-back contact thin film PV cell at another step in a method of fabricating the cell in accordance with an embodiment of the presently described invention.

FIG. 11 illustrates a cross-sectional view of the all-back contact thin film PV cell at another step in a method of fabricating the cell in accordance with an embodiment of the presently described invention.

FIG. 12 illustrates a cross-sectional view of the all-back contact thin film PV cell at another step in a method of fabricating the cell in accordance with an embodiment of the presently described invention.

FIG. 13 illustrates a cross-sectional view of the all-back contact thin film PV cell at another step in a method of fabricating the cell in accordance with an embodiment of the presently described invention.

FIG. 14 illustrates a cross-sectional view of the all-back contact thin film PV cell at another step in a method of fabricating the cell in accordance with an embodiment of the presently described invention.

FIG. 15 illustrates a cross-sectional view of the all-back contact thin film PV cell at another step in a method of fabricating the cell in accordance with an embodiment of the presently described invention.

FIG. 16 illustrates a cross-sectional view of the all-back contact thin film PV cell in accordance with an embodiment of the presently described invention.

FIG. 17 illustrates a flowchart of a method for fabricating an all-back contact thin film PV cell in accordance with an embodiment of the presently described invention.

FIG. 18 illustrates a top view of a schematic diagram of a system in which a plurality of offset sources of focused or directed beams of energy are used to scan a large area substrate including one or more PV cells in accordance with an embodiment of the presently described invention.

FIG. 19 illustrates a top view of a schematic diagram of a system in which one or more offset sources of focused or directed beams of energy are used to scan a large area substrate including one or more PV cells in accordance with an embodiment of the presently described invention.

FIG. 20 illustrates a top view of a schematic diagram of a system in which a plurality of vertically and horizontally offset sources of focused or directed beams of energy are used to scan a large area substrate including one or more PV cells in accordance with an embodiment of the presently described invention.

FIG. 21 illustrates a schematic diagram of an all-back contact PV module in accordance with an embodiment of the presently described invention.

The foregoing summary, as well as the following detailed description of certain embodiments of the presently described technology, will be better understood when read in conjunction with the appended drawings. For the purpose of illustrating the presently described technology, certain embodiments are shown in the drawings. It should be understood, however, that the presently described technology is not limited to the arrangements and instrumentality shown in the attached drawings.

### DETAILED DESCRIPTION OF THE INVENTION

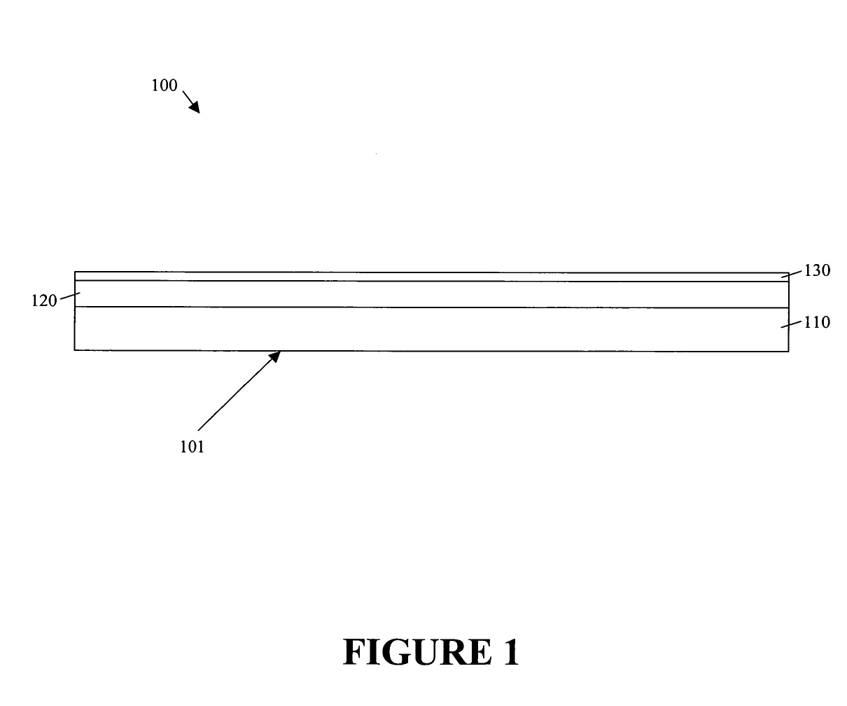

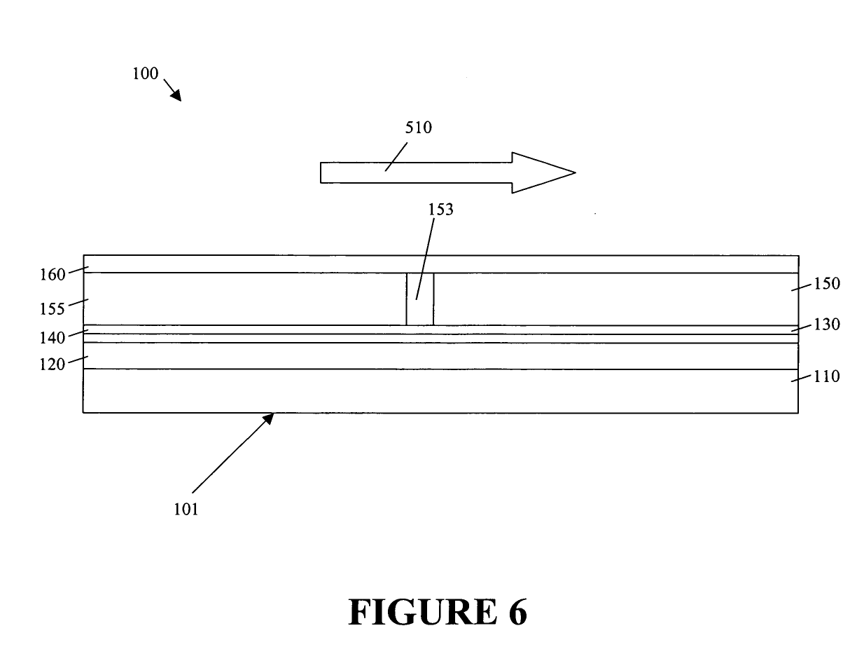

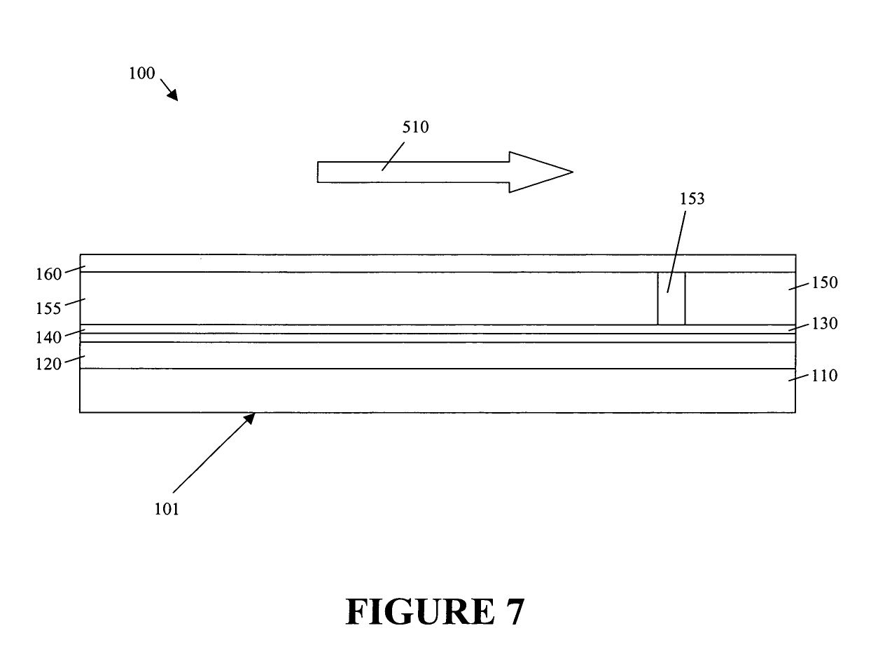

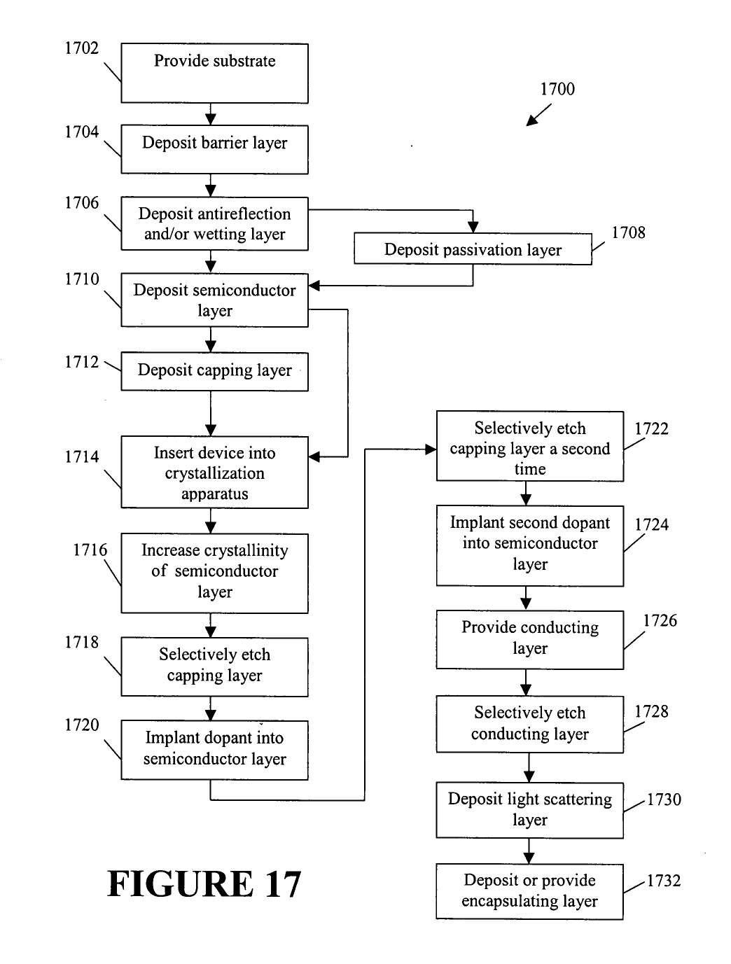

FIG. 17 illustrates a flowchart of a method 1700 for fabricating an all-back contact thin film PV cell in accordance with an embodiment of the presently described invention. Various steps illustrated in FIG. 17 and described herein are illustrated in other figures. For example, FIGS. 1-16 illustrate a cross-section view of a PV cell 100 fabricated in accordance with an embodiment of the presently described invention at one or more of the steps illustrated and described in FIG. 17. In general, cell 100 includes a side 101 that incident light strikes to generate electricity. For example, light incident to cell 100 at side 101 passes through one or more layers of cell 100 (including a substrate 110, as described below) and strikes a semiconductor layer 155 (also described below) to generate electricity.

In accordance with an embodiment of method 1700 and as illustrated in FIG. 1, a substrate 110 is first provided or obtained at step 1702. Substrate 110 preferably comprises a non-conducting material, such as a glass substrate. For example, substrate 110 can comprise float glass, borosilicate glass, or low iron float glass. In addition, substrate 110 is preferably non-opaque to incident light. That is, substrate is optically transparent or translucent. By providing a transparent or translucent substrate, light can strike side 101 of cell 100 and semiconductor layer 155, as described below, that does not have electrical contacts. That is, with the electrical contacts to layer 150 or 155 on one side of cell 100 and a translucent or transparent substrate 110 on the other side 101 of cell 100, light can strike the substrate side 101 of cell 100. This can result in cell 100 having increased efficiency over existing cells that include a substrate that blocks or greatly impedes incident light from striking a semiconductor layer or a PV cell that includes electrical contacts on the same side of the cell as incident light strikes.

In an embodiment, substrate 110 comprises one or more materials having a low softening point. That is, substrate 110 comprises one or more materials that have a relatively low temperature (when compared to more expensive substrates currently used in PV cells, such as quartz) at which the material(s), when unsupported, start to soften and bend. For example, substrate 110 can comprise borosilicate glass, float glass and/or low iron float glass. These glasses can have a softening point below 750° C., which can be a minimum temperature at which many processing steps in fabricating a PV cell are performed. As described above, many processing steps are performed at temperatures of at least 750-2000° C.

Substrate 110 can be provided in a vacuum chamber. The vacuum level of the chamber can be any level sufficient to complete the steps described below. For example, the vacuum level can be 10⁰ to 10⁻⁶ torr. Substrate 110 can be deposited in any thickness sufficient to support the remaining layers of cell 100 while providing mechanical and thermal stability to cell 100 during its processing and handling. For example, substrate 110 can be at least 0.7 to 3.3 mm thick. In an embodiment, substrate 110 comprises a 1.1 mm thick borosilicate glass substrate. In another embodiment, substrate 110 comprises a 3.3 mm thick low iron float glass substrate.

Next, at step 1704, a barrier layer 120 is deposited adjacent to substrate 110, as shown in FIG. 1. For example, barrier layer 120 can be deposited on substrate 110. Barrier layer 120 can be deposited for one or more purposes. For example, barrier layer 120 can be deposited to act as a thermal and/or chemical diffusion barrier to impede or prevent heat in semiconductor layer 150 from reaching substrate 110 and to impede or prevent impurities in substrate 110 from reaching a semiconductor layer 150 that is later deposited near barrier layer 120 (at step 1720, which is described below).

As described below, during a later step where the level of crystallinity of semiconductor layer 150 can be increased, a temperature of cell 100 also can increase. As the temperature increases, impurities present in substrate 110 can become more mobile and diffuse out of substrate 110 into adjacent layers. In order to impede or prevent these impurities from diffusing into semiconductor layer 150, barrier layer 120 can be deposited at step 1704 to impede and/or stop diffusion of these impurities into the semiconductor layer.

In an embodiment, barrier layer 120 is deposited using PECVD. But, other methods or techniques of depositing barrier layer 120 can be utilized in accordance with embodiments of the presently described invention.

Barrier layer 120 can be deposited in a variety of thicknesses. In an embodiment, barrier layer 120 is deposited in a thickness that is less than substrate 110. For example, barrier layer 120 can be deposited in a layer that is approximately 0.5 to 2 μm, or 0.5×10⁻⁶ to 2×10⁻⁶ m, thick. In a more preferred embodiment, barrier layer 120 is deposited to be approximately 1 μm, or 1×10⁻⁶ m, thick. By “approximately,” it is meant that a layer is deposited using available devices, systems and apparatuses with the intention of depositing a layer of a particular thickness, but due to slight variances in this intended thickness that are caused by the device, system or apparatus employed, the intended thickness varies. For example, a variance of +10% of the intended thickness of layer 120 can be acceptable. However, a smaller variance also is within the scope of one or more embodiments of the presently described invention.

Barrier layer 120 can comprise a non-conducting, or insulating material. In an embodiment of the presently described invention, barrier layer 120 comprises SiO₂. For example, barrier layer 120 can comprise SiO₂ of a higher purity level than substrate 110. That is, barrier layer 120 can comprise fewer impurities per unit volume than substrate 110. The increased purity of barrier layer 120 can give it a much higher melting temperature than substrate 110, which can be advantageous for improving the mechanical integrity of the stack of layers, or “layer stack,” of cell 100 during step 1716 where the temperature of semiconductor layer 150 and cell 100 can significantly increase.

Next, at step 1706, a layer 130 is deposited adjacent to barrier layer 120, as shown in FIG. 1. For example, layer 130 can be deposited on barrier layer 120. Layer 130 can comprise a material such as silicon nitride (Si₃N₄). In other embodiments, layer 130 comprises at least one of zinc oxide (ZnO), titanium dioxide (TiO₂), and zinc sulfide (ZnS).

Layer 130 can be deposited for one or more purposes. For example, layer 130 can be deposited as a wetting agent to lower a surface tension of semiconductor layer 150 that is later deposited near or adjacent to layer 130. As described below, during a crystallization step, a temperature of cell 100 can be increased. If the temperature increases a sufficient amount, semiconductor layer 150 can become more fluid and/or melt. In embodiments where layer 130 comprises silicon nitride (Si₃N₄) and semiconductor layer 150 comprises silicon, for example, the nitrogen in layer 130 can help to reduce the surface tension of the silicon in semiconductor layer 150 as layer 150 becomes fluid or melts, thereby reducing or preventing the molten silicon from forming beads during the crystallization step. Thus, in order to lower the surface tension between semiconductor layer 150 and barrier layer 120 so that an interface between barrier layer 120 and semiconductor layer 150 is more uniform, layer 130 can be deposited.

In another example, layer 130 can be deposited as an anti-reflective or antireflection (either term abbreviated as “AR”) coating or layer. In such an embodiment, layer 130 reduces reflection of light that passes into cell 100 from side 101 so that less light is reflected and lost from cell 100.

Layer 130 can be deposited using PECVD in a vacuum environment. But, other methods or techniques of depositing layer 130 can be utilized in accordance with embodiments of the presently described invention.

Layer 130 can be deposited in a variety of thicknesses. In an embodiment, layer 130 is deposited in a thickness that is less than barrier layer 120. For example, layer 130 can be deposited in a layer that is approximately 25 to 200 nanometers (“nm”), or 25×10⁻⁹ to 200×10⁻⁹ m, thick. In a more preferred embodiment, layer 120 is deposited in a layer approximately 50 to 100 nm, or 50×10⁻⁹ to 100×10⁻⁹ m, thick. By “approximately” with respect to layer 130, it is meant that a layer is deposited using available devices, systems and apparatuses with the intention of depositing a layer of a particular thickness, but due to slight variances in this intended thickness that are caused by the device, system or apparatus employed, the intended thickness varies. For example, a variance of +20% in layer 130 of the intended thickness can be acceptable. However, a smaller variance also is within the scope of one or more embodiments of the presently described invention.

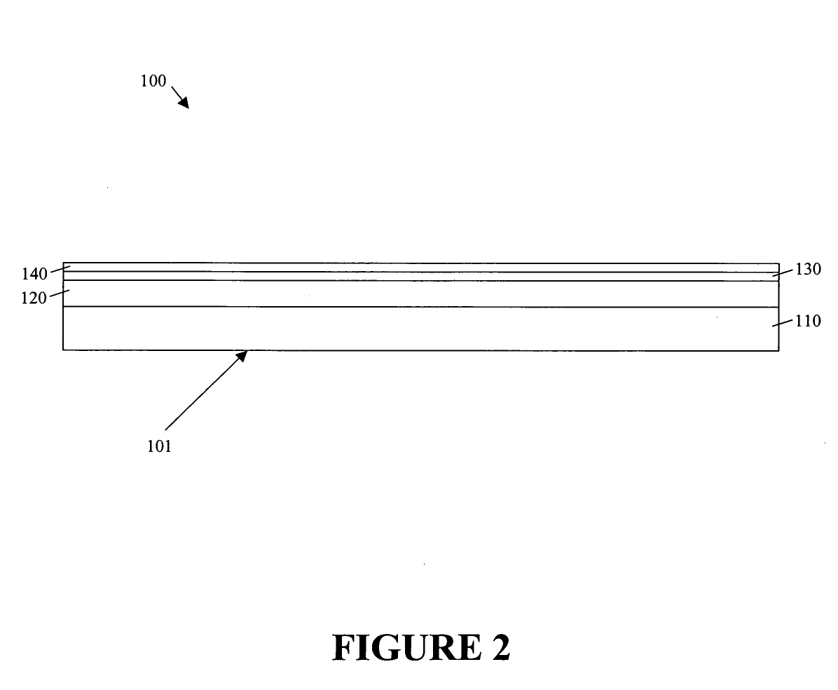

In an embodiment, once layer 130 is deposited at step 1706, method 1700 proceeds to step 1708 where a passivation layer 140 is deposited adjacent to layer 130, as shown in FIG. 2.

Alternatively, in another embodiment, once layer 130 is deposited at step 1706, method 1700 proceeds from step 1706 to step 1710 where semiconductor layer 150 is deposited adjacent to layer 130. In such an embodiment, the passivation layer 140 that is shown between semiconductor layer 150 and layer 130 in FIGS. 2 through 16 is absent. Thus, semiconductor layer 150 is adjacent to layer 130. While FIGS. 2 through 16 illustrate cell 100 with passivation layer 140 present, it is to be understood that in an embodiment of the presently described invention, passivation layer 140 may be absent from cell 100, with semiconductor layer 150 and layer 130 being adjacent to one another.

At step 1708, passivation layer 140 is deposited adjacent to layer 130, as shown in FIG. 2. For example, passivation layer 140 can be deposited on layer 130. Passivation layer 140 can comprise a non-conducting, or insulating material. In an embodiment of the presently described invention, passivation layer 140 comprises SiO₂. For example, passivation layer 140 can comprise SiO₂ of a higher purity level than substrate 110 and/or barrier layer 120. That is, passivation layer 140 can comprise fewer impurities per unit volume than substrate 110 and/or barrier layer 120.

Passivation layer 140 can be deposited for one or more purposes. For example, passivation layer 140 can be deposited to make semiconductor layer 150 more passive relative to layer 130 (and vice-versa) when semiconductor layer 150 is heated at step 1716, as described in more detail below. In an embodiment where layer 140 comprises silicon dioxide (SiO₂), such a layer can electrically passivate a silicon surface because layer 140 can reduce or minimize the number of dangling bonds on a surface of semiconductor layer 150.

Passivation layer 140 can be deposited using PECVD in a vacuum environment. But, other methods or techniques of depositing passivation layer 140 can be utilized in accordance with embodiments of the presently described invention.

Passivation layer 140 can be deposited in a variety of thicknesses. In an embodiment, passivation layer 140 is deposited in a thickness less than layer 130 and/or barrier layer 120. For example, passivation layer 140 can be deposited in a layer that is approximately 1 to 40 nm, or 1×10⁻⁹ to 40×10⁻⁹ m, thick. In a preferred embodiment, passivation layer 140 is deposited in a layer approximately 10 nm or less, or 10×10⁻⁹ m or less, thick. By “approximately” with respect to layer 140, it is meant that a layer is deposited using available devices, systems and apparatuses with the intention of depositing a layer of a particular thickness, but due to slight variances in this intended thickness that are caused by the device, system or apparatus employed, the intended thickness varies. For example, a variance of ±50% in layer 140 of the intended thickness can be acceptable. However, a smaller variance also is within the scope of one or more embodiments of the presently described invention.

In an embodiment of the presently described invention, passivation layer 140 can be intentionally doped with one or more impurity atoms. In such an embodiment, passivation layer 140 can act as a diffusion source for doping one side of semiconductor layer 150 when a temperature of cell 100 is increased during step 1716, as described below. For example, passivation layer 140 can be doped with boron (B) or phosphorous (P). In one embodiment, passivation layer 140 is doped with a p-type dopant, such as boron.

In such an embodiment, dopants in passivation layer 140 can diffuse from layer 140 into semiconductor layer 150 and thereby increase the dopant concentration in semiconductor layer 150 in a volume near or adjacent to passivation layer 140. The dopant concentration in passivation layer 140 can vary based on the needs of the source of dopants, the temperature at which passivation layer 140 is heated, and the desired dopant concentration in the volume of semiconductor layer 150 near or adjacent to passivation layer. In an embodiment, for example, the dopant concentration in passivation layer 140 can range from approximately 0.001 to 5 atomic percent. By “approximately” with respect to layer 140, it is meant that passivation layer 140 is doped using available devices, systems and apparatuses with the intention of doping layer 140 to an intended dopant concentration, but due to slight variances in the dopant concentration that are caused by the device, system or apparatus employed, the intended dopant concentration varies. For example, a variance of +100% in the dopant concentration of layer 140 can be acceptable. However, a smaller variance also is within the scope of one or more embodiments of the presently described invention

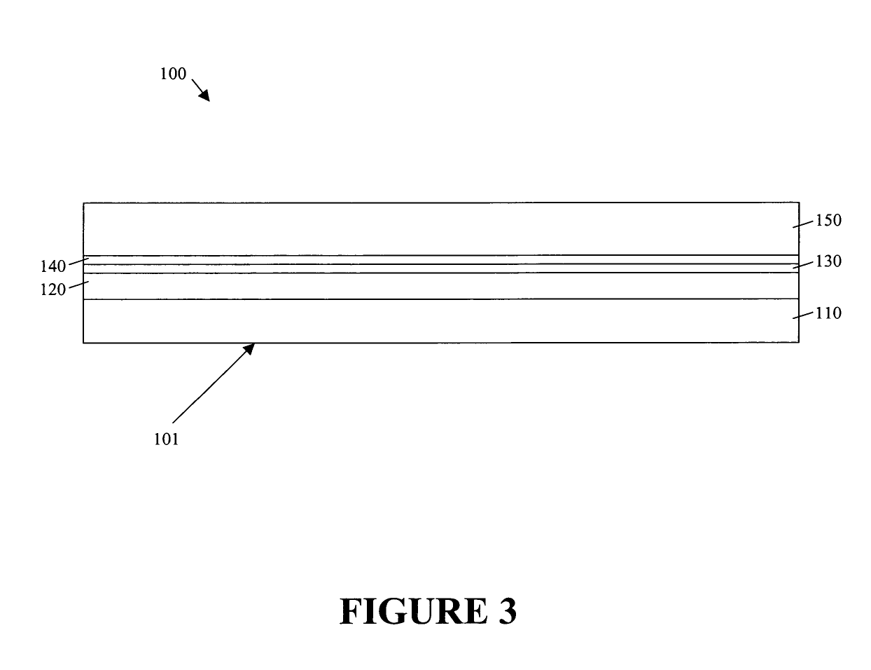

After step 1706, or steps 1706 and 1708, method 1700 proceeds to step 1710. At step 1710, semiconductor layer 150 is deposited adjacent to passivation layer 140 (in the embodiment where method 1700 proceeds from step 1706 to step 1708 to step 1710), as shown in FIG. 3, or adjacent to layer 130 (in the embodiment where method 1700 proceeds from step 1706 to step 1710).

Semiconductor layer 150 can be deposited in cell 100 to absorb photons from light striking side 101 of cell 100 and passing through substrate 110, barrier layer 120, layer 130 and, if included, passivation layer 140. As photons strike semiconductor layer 150, electrons and holes in semiconductor layer 150 can begin to flow through layer 150 to produce electricity.

Semiconductor layer 150 can be deposited using PECVD in a vacuum environment. But, other methods or techniques of depositing semiconductor layer 150 can be utilized in accordance with embodiments of the presently described invention. Semiconductor layer 150 can comprise a semiconductor material. For example, semiconductor layer 150 can include silicon (Si). In another embodiment, semiconductor layer 150 can include one or more of germanium (Ge) and gallium arsenide (GaAs). In addition, other compound semiconductors can be used in or as layer 150.

Semiconductor layer 150 can be deposited in a variety of thicknesses. In an embodiment, semiconductor layer 150 is deposited in a thickness that is sufficiently small that the minority carrier diffusion length in semiconductor layer 150 is larger than the thickness of layer 150. For example, the minority carrier diffusion length can be at least two to four times longer than the thickness of layer 150. In another example, the minority carrier diffusion length can be at least five to ten times longer than the thickness of layer 150. In an embodiment of the presently described invention, semiconductor layer 150 is deposited at a thickness that is less than the thickness of an electronic grade silicon wafer.

In an embodiment, semiconductor layer 150 is deposited in a thickness of approximately 1 to 100 μm, or 1×10⁻⁶ to 100×10⁻⁶ m. In a more preferred embodiment, semiconductor layer 150 is deposited in a thickness of approximately 1 to 50 μm, or 1×10⁻⁶ to 50×10⁻⁶ m. In a more preferred embodiment, semiconductor layer 150 is deposited in a thickness of approximately 1 to 20 μm, or 1×10⁻⁶ to 20×10⁻⁶ m. In a more preferred embodiment, semiconductor layer 150 is deposited in a thickness of approximately 10 μm, or 10×10⁻⁶ m, or less. In a more preferred embodiment, semiconductor layer 150 is deposited in a thickness of approximately 5 μm, or 5×10⁻⁶ m. By “approximately” with respect to layer 150, it is meant that a layer is deposited using available devices, systems and apparatuses with the intention of depositing a layer of a particular thickness, but due to slight variances in this intended thickness that are caused by the device, system or apparatus employed, the intended thickness varies. For example, a variance of +10% in layer 150 of the intended thickness can be acceptable. However, a smaller variance also is within the scope of one or more embodiments of the presently described invention.

In another example, semiconductor layer 150 can be deposited in a thickness that is greater than each or any of barrier layer 120, layer 130 and passivation layer 140. In addition, semiconductor layer 150 can be deposited so as to have a thickness that is greater than each or any of the other layers in cell 100 other than substrate 110, a capping layer 160, a conducting layer 170, light scatting layer 180 and/or an encapsulating layer 190.

Semiconductor layer 150 can be deposited in an amorphous, or non-crystalline, state or in a microcrystalline state. For example, semiconductor layer 150 can comprise silicon that is deposited so as to have little to no long-range molecular lattice structure that is characteristic of a crystalline material, or so as to have small crystal volumes throughout layer 150 but without any crystalline lattice structure that exists over a substantial volume of layer 150. In an embodiment, a “level of crystallinity” for semiconductor layer 150 is a measurement of the amount of crystallinity in layer 150. For example, the amount or level of crystallinity can be measured by determining a mean or median crystal grain size in layer 150, or by measuring a volume fraction of crystalline material in layer 150.

In an embodiment of the presently described invention, semiconductor layer 150 is an intrinsic material. For example, semiconductor layer 150 can include silicon that has not been intentionally or purposefully doped with a dopant. Alternatively, semiconductor layer 150 is a uniformly doped material. By “uniformly doped material,” it is meant that layer 150 includes a semiconductor that is intentionally or purposefully doped with a dopant throughout layer 150 so that no dopant junction is intentionally or purposefully created in layer 150.

Semiconductor layer 150 can thus be doped with p or n charge dopants, such as boron or phosphorus, for example. Layer 150 can be doped at a variety of concentrations. For example, in an embodiment, layer 150 can be doped with p or n dopants at a concentration of 1×10¹⁴ to 1×10¹⁸/cm³. In a more preferred embodiment, layer 150 can be doped with p or n dopants at a concentration of 1×10¹⁵ to 1×10¹⁷/cm³. However, other dopant concentrations can be acceptable and within the scope of one or more embodiments of the presently described invention. In an embodiment where passivation layer 140 is doped with p-type impurities, layer 150 can also be doped with p-type impurities, for example. In such an embodiment, the dopant concentration of the p-type impurities can be 10 to 1000 times greater in passivation layer 140 than in semiconductor layer 150.

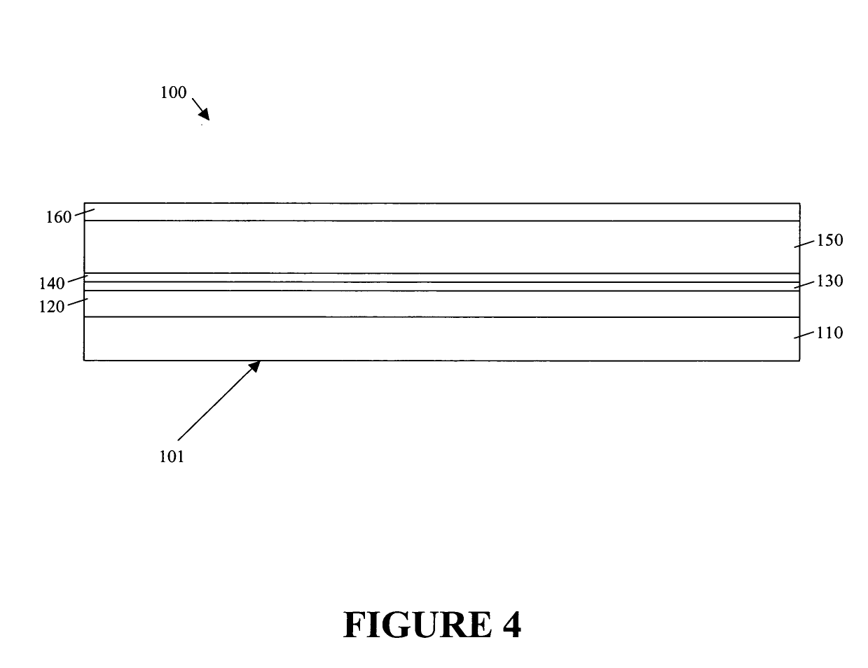

Next, at step 1712, capping layer 160 is deposited adjacent to semiconductor layer 150, as shown in FIG. 4. For example, capping layer 160 can be deposited on semiconductor layer 150. In an alternate embodiment of the presently described invention, capping layer 160 is not utilized. That is, no capping layer 160 is deposited at step 1712. Instead, method 1700 proceeds from step 1710 to step 1714. While FIGS. 4 through 16 illustrate cell 100 with capping layer 160 present, in the embodiments of the presently described invention where no capping layer 160 is utilized, FIGS. 4 through 16 are otherwise similar or identical to those illustrated herein, with the exception that capping layer 160 is absent.

Capping layer 160 can be deposited for one or more purposes. For example, capping layer 160 can be deposited as a wetting agent to lower a surface tension of semiconductor layer 150 during step 1716 when the temperature of layer 150 can be increased. As described above and below, in an embodiment of the presently described invention, a temperature of cell 100 can increase during a crystallization step. As the temperature increases, semiconductor layer 150 can become more fluid and/or melt. In embodiments where capping layer 160 comprises SiO₂ or silicon nitride (Si₃N₄) and semiconductor layer 150 comprises silicon, the nitrogen in capping layer 160 helps to reduce the surface tension in the silicon in semiconductor layer 150 if layer 150 becomes more fluid or melts. Without capping layer 160, the silicon in semiconductor layer 150 can tend to bead up if layer 150 becomes more fluid or melts. With capping layer 160, this beading up problem can be reduced or avoided by creating a more uniform surface on semiconductor layer 150 if layer 150 is heated or melts.

Capping layer 160 also can be utilized to reduce the number of patterning steps required for defining junctions in semiconductor layer 150 or 155, as described below. The patterning and selective etching of capping layer 160 in cell 100 is described below. Generally, one benefit to including capping layer 160 is that it can be patterned and etched a first time to expose a first set of exposed areas of semiconductor layer 150 or 155. These first exposed areas (and corresponding volumes of semiconductor layer 150 or 155) can then be doped with a first type of dopant. Capping layer 160 can then be patterned and etched a second time to expose a second set of exposed areas of layer 150. In an embodiment, the second set of areas can include or encompass the first set of areas in addition to previously unexposed areas of semiconductor layer 150 or 155. The second exposed areas (and corresponding volumes of semiconductor layer 150 or 155) can then be doped with a second type of dopant. Where the first and second types of dopants include opposing charge carriers and the second set of exposed areas encompasses the first set of exposed areas (and the corresponding volumes of semiconductor layer 150 or 155), the amount or concentration of dopants can be carefully monitored to avoid compensating the first dopant in the first set of exposed areas and corresponding volumes with the second dopant in these same areas and corresponding volumes.

In an embodiment that does not include capping layer 160, multiple steps of depositing an insulating mask, patterning the mask, etching away portions of the mask to expose a first set of areas of semiconductor layer 150 or 155, doping layer 150 at the first set of exposed areas and corresponding volumes, removing the rest of mask, depositing another insulating mask, patterning the second mask, etching away portions of the mask to expose a second set of areas of semiconductor layer 150 or 155, doping layer 150 again at the second set of exposed areas and corresponding volumes, removing the rest of the second mask, and so on, may be required to achieve the same junction location and profile as is obtainable using capping layer 160. For example, utilizing photolithography tools and materials such as ultraviolet light and photoresist, one or more masks can be deposited, patterned and etched to obtain multiple doped regions or volumes in semiconductor layer 150 or 155.

Capping layer 160 can be deposited using PECVD in a vacuum environment. But, other methods or techniques of depositing capping layer 160 can be utilized in accordance with embodiments of the presently described invention. In an embodiment, capping layer 160 comprises Si₃N₄ or SiO₂. For example, capping layer 160 can comprise SiO₂ of a higher purity level than substrate 110 and/or barrier layer 120. That is, capping layer 160 can comprise fewer impurities per unit volume than substrate 110 and/or barrier layer 120.

Capping layer 160 can be deposited in a variety of thicknesses. In an embodiment, capping layer 160 is deposited in a thickness that is less than semiconductor layer 150 and/or greater than one or more of layer 130 and passivation layer 140. For example, capping layer 160 can be deposited in a layer that is approximately 0.1 to 1 μm (or 0.1×10⁻⁶ to 1×10⁻⁶ m) thick. In another embodiment, capping layer 160 can be deposited in a layer that is approximately 0.5 to 1 μm (0.5×10⁻⁶ to 1×10⁻⁶ m) thick. In a preferred embodiment, capping layer 160 is deposited so as to be approximately 0.25 to 1 μm (0.25×10⁻⁶ to 1×10⁻⁶ m) thick. By “approximately” with respect to layer 160, it is meant that a layer is deposited using available devices, systems and apparatuses with the intention of depositing a layer of a particular thickness, but due to slight variances in this intended thickness that are caused by the device, system or apparatus employed, the intended thickness varies. For example, a variance of +10% in layer 160 of the intended thickness can be acceptable. However, a smaller variance also is within the scope of one or more embodiments of the presently described invention.

Capping layer 160 can be intentionally doped with one or more impurity atoms, similar to that of passivation layer 140. In such an embodiment, capping layer 160 can act as a diffusion source for doping one side of semiconductor layer 150 if a temperature of cell 100 is increased during step 1716, as described below. For example, capping layer 160 can be doped with boron (B) or phosphorous (P). In an embodiment where cell 100 (including capping layer 160) is heated during step 1716 (as described below), dopants in capping layer 160 can diffuse from layer 160 into semiconductor layer 150 and thereby increase the dopant concentration in semiconductor layer 150 in at least a volume near or adjacent to capping layer 160.

A dopant concentration in capping layer 160 can vary based on the needs of the source of dopants, the temperature at which capping layer 160 is heated, and the desired dopant concentration in the volume of semiconductor layer 150 near or adjacent to passivation layer. In an embodiment, for example, the dopant concentration in capping layer 160 can be approximately 0.001 to 5 atomic percent. By “approximately” with respect to layer 160, it is meant that capping layer 160 is doped using available devices, systems and apparatuses with the intention of doping layer 160 to an intended dopant concentration, but due to slight variances in the dopant concentration that are caused by the device, system or apparatus employed, the intended dopant concentration varies. For example, a variance of +100% in the dopant concentration of layer 160 can be acceptable. However, a smaller variance also is within the scope of one or more embodiments of the presently described invention.

In an embodiment where passivation layer 140 is doped with p-type dopants or impurities at a greater concentration than the doping of layer 150 with p-type dopants, capping layer 160 can be doped with n-type impurities or dopants, for example. In such an embodiment, the dopant concentration of the n-type dopants can be 10 to 100 times greater than the concentration of p-type dopants in semiconductor layer 150. In addition, the concentration of the n-type dopants can be of the same order of magnitude as the concentration of p-type dopants in passivation layer 140. However, other dopant concentrations are intended to fall within the scope of one or more embodiments of the presently described invention.

In an embodiment of the presently described invention, each of steps 1704 through 1712 (including step 1708 if such an embodiment is employed) is performed in a vacuum chamber. For example, each of these steps can be performed in a chamber where the pressure is no greater than 10⁰ to 10⁻⁶ torr. These steps can all be performed in a single chamber or can be performed in multiple chambers. For example, in an embodiment where PECVD is used to deposit the layers described above, the depositions can be done in one chamber by changing the gases that flow into the chamber. For silicon nitride, for example, a combination of silane (SiH₄) and ammonia (NH₃) can be used. For p-type silicon, silane and tri-methyl boron (B(CH₃)₃) can be used. If sputtering is used, the depositions can be done in one chamber by using multiple sputter targets of different composition.

After step 1712, method 1700 proceeds to step 1714. In an embodiment where step 1712 is excluded, method 1700 proceeds from step 1710 to step 1714. At step 1714, cell 100 is placed into a chamber or system used to increase the crystallinity level in semiconductor layer 150 (referred to herein as a “crystallization apparatus”). Such a chamber or system can be used to rapidly and controllably heat the semiconductor film by using a scanned, focused beam of energy. The crystallization apparatus includes any chamber or system capable of exposing at least layer 150 to one or more directed or focused beams of energy so as to increase a level of crystallinity of layer 150. For example, the crystallization apparatus can include one or more chambers housing cell 100 and one or more e-beam sources or laser beam sources.

In an embodiment, the crystallization apparatus or system is connected to the chamber or chambers utilized in steps 1704 through 1710 (or steps 1704 through 1712), including step 1708 if that embodiment is employed. In such an embodiment, cell 100 can be transferred from the chamber(s) used in the previous steps into the crystallization apparatus or system while maintaining the vacuum level used in the previous steps. Alternatively, cell 100 is removed from the chamber(s) used in previous steps and placed into the crystallization apparatus or system for step 1714.

Once cell 100 is in the crystallization apparatus, if a vacuum level has not yet been established or has not been maintained, a vacuum level is then created or re-established. Alternatively, if a vacuum level is already established and has not been destroyed or compromised by transferring cell 100 into the crystallinity chamber or system, then the vacuum level can be maintained. In an embodiment, the pressure is no greater than 10⁰ to 10⁻⁶ torr.

Once cell 100 is in the crystallization apparatus, method 1700 proceeds to step 1716. At step 1716 a level of crystallinity of semiconductor layer 150 is increased. As described above, a “level of crystallinity” for semiconductor layer 150 is defined in various embodiments of the presently described invention as a measurement of the amount of crystallinity in layer 150. For example, the amount or level of crystallinity can be measured by determining a mean or median crystal grain size in layer 150, and/or by measuring a volume fraction of crystalline material in layer 150.

At step 1716, this level of crystallinity is increased. In an embodiment, a level of crystallinity of layer 150 increases when the mean or median grain size of crystalline material in layer 150, and/or volume fraction of crystalline material in layer 150 increases by a measurable, statistically significant amount. Thus, the mean or median grain size in semiconductor layer 150, and/or the volume fraction of crystalline material in layer 150, after step 1716 is greater than it was prior to step 1716. By “greater,” it is meant that the mean or median grain size for layer 150, and/or the volume fraction of crystalline material in layer 150, has increased by some measurable difference. For example, the level of crystallinity can increase at least an amount that is greater than any noise or uncertainty introduced into measurements by a measuring instrument, for example. In other words, the mean or median grain size or the volume fraction of crystalline material has not decreased or remained the same. In an embodiment, the level of crystallinity is considered to increase when (1) a mean crystal grain size in layer 150, (2) a median crystal grain size in layer 150 and (3) a volume fraction of crystalline material in layer 150 both increase. In another embodiment, the level of crystallinity is considered to increase when (1) a mean crystal grain size in layer 150, (2) a median crystal grain size in layer 150 or (3) a volume fraction of crystalline material in layer 150 increases.

In an embodiment, cell 100 is exposed to one or more focused or directed beams of energy from one or more sources at step 1716. The beams of energy can comprise any one or more of e-beams or lasers, for example. While the discussion here focuses on e-beams, lasers and laser sources can be utilized in place of e-beams and e-beam sources in accordance with one or more embodiments of the presently described invention.

In an embodiment, the crystallinity level of layer 150 is increased by utilizing a technique known as Zone-Melting Recrystallization (“ZMR”). Generally, ZMR includes heating a layer at a temperature approaching the layer's melting point or above the layer's melting point. The source of heat typically moves relative to the layer. As the heat source moves away from a section of the layer that has been heated near or to its melting point, the section cools and crystallizes or recrystallizes.

In an embodiment of the presently described invention, step 1716 includes placing cell 100 into a crystallization system 1800 and exposing layer 150 to one or more focused or directed beams of energy, such as lasers or e-beams. In an embodiment, the beams of energy are scanning e-beams that move relative to layer 150. During this step, layer 150 undergoes melting and crystallization in accordance with a traditional ZMR process. Thus, after step 1716, a level of crystallinity in layer 150 is increased.

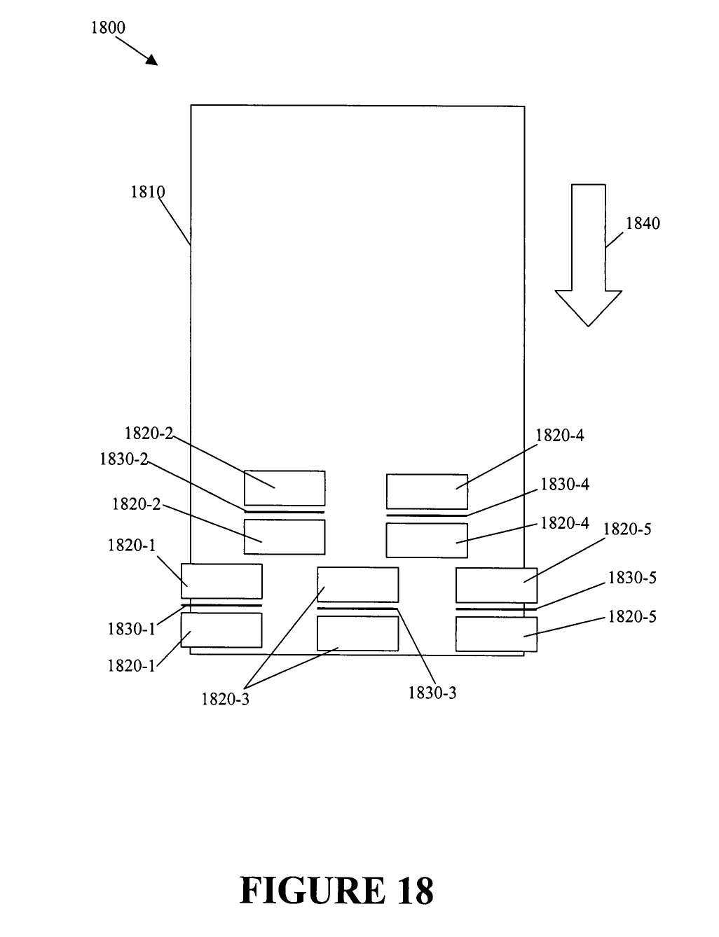

As described above, existing systems and methods that employ focused or directed beams of energy, such as lasers or e-beams and sources of focused or directed beams of energy to obtain a crystallization pattern over a large-area substrate or layer cannot cover large areas of substrates and/or take a relatively long time to cover a large-area substrate. One or more embodiments of the presently described invention provide solutions to at least these problems. For example, FIG. 18 illustrates a top view of a schematic diagram of system 1800 in which a plurality of offset sources of focused or directed beams of energy are used to scan a large area substrate 1810 including one or more PV cells 100 in accordance with an embodiment of the presently described invention. Again, while the discussion here focuses on e-beams, lasers and laser sources can be utilized in place of e-beams and e-beam sources in accordance with one or more embodiments of the presently described invention. In addition, while the discussion here addresses the length of an emitted e-beam line, the discussion applies equally well to the width of a rastered point e-beam.

System 1800 includes a plurality of e-beam sources spatially offset from one another. In an embodiment, each source is a Pierce reflector that includes a plurality of reflectors 1820 and a filament 1830. In alternative embodiments, each source includes a point source e-beam that is focused using magnetic fields. While the e-beam sources in system 1800 are illustrated as comprising a Pierce reflector that includes a plurality of reflectors 1820 and a filament 1830, other e-beam sources are contemplated and encompassed in one or more embodiments of the presently described invention.

As shown in FIG. 18, the reference number for each of the reflectors and filament includes an additional number such as −1, −2, −3, −4 or −5. This additional number is used to clarify to which reflector 1820 and filament 1830 set is referred in this discussion.

Substrate 1810 can be embodied in one or more cells 100 described herein. That is, substrate 1810 can include one or more cells 100 that each include semiconductor layer 150. Substrate 1810 preferably is of sufficient size or area that a single e-beam source cannot emit an e-beam so as to cover all of substrate 1810 or all of a width of substrate 1810 at once. That is, substrate 1810 is preferably wider than the length of a line e-beam or the raster pattern of a point-e-beam emitted by each e-beam source. For example, if the length of a line e-beam is 2 to 10 cm, then substrate 1810 can have a width that is greater than 10 cm and/or a total area that is greater than 1 m².

In another example, the length of a line e-beam can be a fraction of the width of substrate 1810. For example, each line e-beam can have a length that is approximately one-fifth, one-quarter, one-third or one-fourth of the width of substrate 1810. By “approximately,” it is meant that a line e-beam is emitted using available e-beam devices, systems and apparatuses with the intention of emitting a line beam of a particular length, but due to slight variances in this length that are caused by the device, system or apparatus employed, the intended beam length varies. For example, a variance of +10% of the intended line e-beam length can be acceptable. However, a smaller variance also is within the scope of one or more embodiments of the presently described invention.

In order to cover a large-area substrate 1810, a plurality of e-beam sources are offset from one another. As shown in FIG. 18, the e-beam sources are offset from one another in two directions from one another. For example, the e-beam sources can be spatially offset from one another in two orthogonal or approximately orthogonal directions in a plane parallel to substrate 1810. With respect to the embodiment illustrated in FIG. 18, the e-beam sources are offset in a left/right direction and an up/down direction of the page. In such a configuration, the total e-beams produced by the sources can cover a larger area, if not all, of a width of substrate 1810. For example, a line e-beam from a first filament 1830-1 and set of reflectors 1820-1 can cover a portion of a width of substrate 1810. Another filament 1830-2 and set of reflectors 1820-2 can emit a line e-beam that covers an adjacent and/or overlapping portion of the width of substrate 1810. As shown in FIG. 18, first filament 1830-1 and reflectors 1820-1 can emit an e-beam line that covers less than the entire width of substrate 1810. Second filament 1830-2 and reflectors 1820-2 can emit an e-beam line that covers less than the entire width of substrate 1810 and a different portion of this width than first filament 1830-1 and reflectors 1820-1. Continuing in this manner, each of filaments 1830-1, 1830-2, 1830-3, 1830-4 and 1830-5 and reflectors 1820-1, 1820-2, 1820-3, 1820-4 and 1820-5 can emit an e-beam line that covers less than the entire width of substrate 1810 and a different portion of this width than each other. However, when the width of substrate 1810 exposed to e-beams transmitted by each of filaments 1830-1, 1830-2, 1830-3, 1830-4 and 1830-5 and reflectors 1820-1, 1820-2, 1820-3, 1820-4 and 1820-5, the total width of substrate 1810 can be exposed to e-beams. Thus, a larger width of substrate 1810 is exposed to e-beams at approximately the same time or simultaneously than with a single e-beam source.

While some reflectors 1820 and filaments 1830 are vertically offset with respect to one another (specifically, reflectors 1820-2 and 1820-4 and filaments 1830-2 and 1830-4), substrate 1810 and/or reflectors 1820 and filaments 1830 can move relative to one another to enable substrate 1810 to be uniformly exposed to e-beams. In an embodiment, e-beam filaments 1830 and reflectors 1820 in system 1800 remain stationary while substrate 1810 moves relative to filaments 1830 and reflectors 1820. For example, substrate 1810 can move in the direction of arrow 1840 (or in a direction opposite of arrow 1840). Alternatively, filaments 1830 and reflectors 1820 can move relative to substrate 1810 while substrate 1810 remains stationary. In addition, substrate 1810 and/or filaments 1830 and reflectors 1820 can move in directions other than that of arrow 1840 in order to ensure that a greater area of substrate 1810 is exposed to e-beams, if necessary.

In an embodiment, the sum total of the e-beam lines emitted by reflectors 1820 and filaments 1830 or rastered e-beam points can cover the entire width of substrate 1810 so that a single pass of substrate 1810 moving relative to reflectors 1820 and filaments 1830 is all that is necessary to perform ZMR on layer 150 of cell(s) 100 in substrate 1810. That is, once substrate 1810 moves relative to reflectors 1820 and filaments 1830 so that reflectors 1820 and filaments 1830 pass over an entire length of substrate 1810, the entire area of substrate 1810 should have been exposed to an e-beam emitted by at least one of reflectors 1820 and filaments 1830.

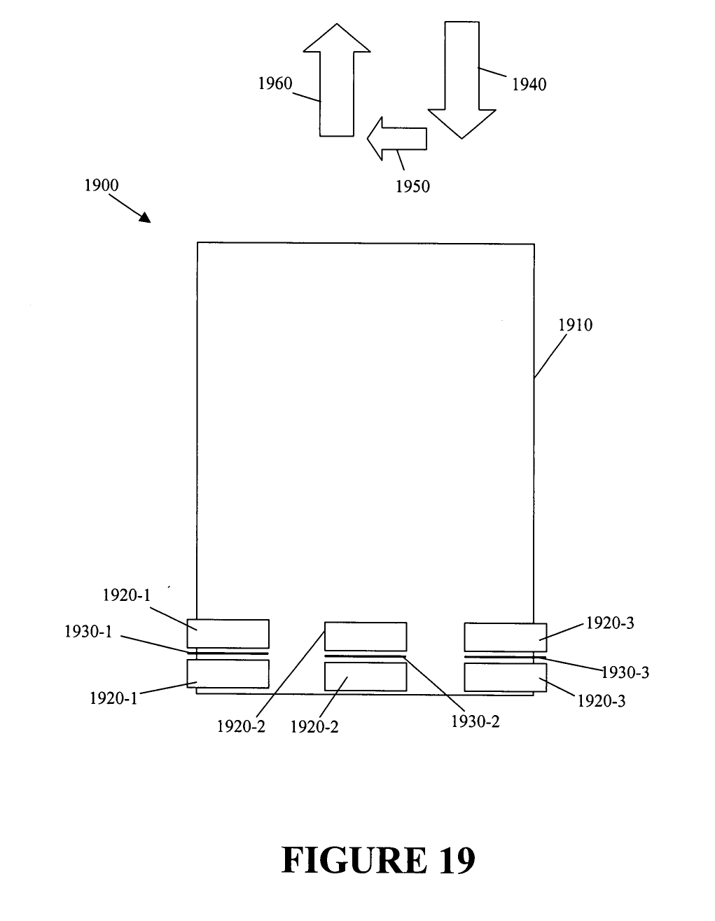

In another embodiment, FIG. 19 illustrates a top view of a schematic diagram of a system 1900 in which one or more offset sources of focused or directed beams of energy are used to scan a large area substrate 1910 including one or more PV cells 100 in accordance with an embodiment of the presently described invention. While the discussion here focuses on e-beams, lasers and laser sources can be utilized in place of e-beams and e-beam sources in accordance with one or more embodiments of the presently described invention. Also, while the discussion here focuses on the length of an emitted e-beam line, it applies equally well to a rastered e-beam point.

System 1900 includes a plurality of e-beam sources spatially offset from one another. In an embodiment, each source is a Pierce reflector that includes a plurality of reflectors 1920 and a filament 1930. In alternative embodiments, each source includes a point source e-beam that is focused using magnetic fields. While the e-beam sources in system 1900 are illustrated as comprising a Pierce reflector that includes a plurality of reflectors 1920 and a filament 1930, other e-beam sources are contemplated and encompassed in one or more embodiments of the presently described invention.

As shown in FIG. 19, the reference number for each of the reflectors and filament includes an additional number such as −1, −2, −3, −4 or −5. This additional number is used to clarify to which reflector 1920 and filament 1930 set is referred in this discussion.

Similar to substrate 1810, substrate 1910 can be embodied in one or more cells 100 described herein. That is, substrate 1910 can include one or more cells 100 that each include semiconductor layer 150. Substrate 1910 preferably is of sufficient size or area that a single e-beam source cannot emit an e-beam so as to cover all of substrate 1910 or all of a width of substrate 1910 at once. That is, substrate 1910 is preferably wider than the width of a line e-beam or the raster pattern of a point-e-beam emitted by each e-beam source. For example, if the length of a line e-beam is 2 to 10 cm, then substrate 1910 can have a width that is greater than 10 cm and/or a total area that is greater than 1 m².

In another example, the length of a line e-beam can be a fraction of the width of substrate 1910. For example, each line e-beam can have a length that is approximately one-fifth, one-quarter, one-third or one-fourth of the width of substrate 1910. Again, by “approximately,” it is meant that a line e-beam is emitted using available e-beam devices, systems and apparatuses with the intention of emitting a line beam of a particular length, but due to slight variances in this length that are caused by the device, system or apparatus employed, the intended beam length varies. For example, a variance of +10% of the intended line e-beam length can be acceptable. However, a smaller variance also is within the scope of one or more embodiments of the presently described invention.

In order to cover a large-area substrate 1910, a plurality of e-beam sources are offset from one another. For example, the e-beam sources can be spatially offset from one another in a single direction. With respect to the page of FIG. 19, the e-beam sources are offset in a left/right direction. In such a configuration, the total of e-beams produced by the sources can cover a larger area, if not all, of a width of substrate 1910. For example, a line e-beam from a first filament 1930-1 and set of reflectors 1920-1 can cover a portion of a width of substrate 1910. Another filament 1930-2 and set of reflectors 1920-2 can emit a line e-beam that covers an adjacent but not overlapping portion of the width of substrate 1910. That is, the e-beam lines emitted by each of reflectors 1920 and filaments 1930 do not overlap one another.

As shown in FIG. 19, first filament 1930-1 and reflectors 1920-1 can emit an e-beam line that covers less than the entire width of substrate 1910. Second filament 1930-2 and reflectors 1920-2 can emit an e-beam line that covers less than the entire width of substrate 1910 and a different portion of this width than first filament 1930-1 and reflectors 1920-1. Continuing in this manner, each of filaments 1930-1, 1930-2 and 1930-3 and reflectors 1920-1, 1920-2 and 1920-3 can emit an e-beam line that covers less than the entire width of substrate 1910 and a different portion of this width than each other.

However, when the width of substrate 1910 exposed to e-beams transmitted by each of filaments 1930-1, 1930-2 and 1930-3 and reflectors 1920-1, 1920-2 and 1920-3, the total width of substrate 1910 may not be exposed to e-beams. That is, the width of the line e-beam from each of filaments 1930-1, 1930-2 and 1930-3 and reflectors 1920-1, 1920-2 and 1920-3 may not overlap an adjacent line e-beam from an adjacent filament 1930. In order to enable system 1900 to expose the entire width and/or area of substrate 1910 to e-beams, substrate 1910 and/or reflectors 1920 and filaments 1930 can move relative to one another. In an embodiment, e-beam filaments 1930 and reflectors 1920 in system 1900 remain stationary while substrate 1910 moves relative to filaments 1930 and reflectors 1920.

In an embodiment, substrate 1910 is moved in a first direction indicated by arrow 1940 while the e-beams emitted by filaments 1930 strike substrate 1910. Substrate 1910 is then moved laterally with respect to arrow 1940, or moved in a direction indicated by arrow 1950. Substrate 1910 is then moved in a direction opposite arrow 1940, or in a direction indicated by arrow 1960. This is referred to as a “scan and stop” process. The scan and step process illustrated in FIG. 19 can be continued until all of or a desired area of substrate 1910 has been exposed to e-beams.

The amount by which substrate 1910 is moved laterally in the direction of arrow 1950 and/or in the direction of arrows 1940 and/or 1960 can be varied so that a larger or fewer number of movements along the directions indicated by arrows 1940 and 1960 are required, or so that the total area scanned by a single e-beam source can be varied.

In another embodiment, filaments 1930 and reflectors 1920 can be moved in the scan and step technique described above while substrate 1910 remains stationary. In another embodiment, substrate 1910 or the e-beam sources can be moved along the direction indicated by arrow 1960, followed by lateral movement in the direction of arrow 1950 and then followed by movement along the direction indicated by arrow 1940.

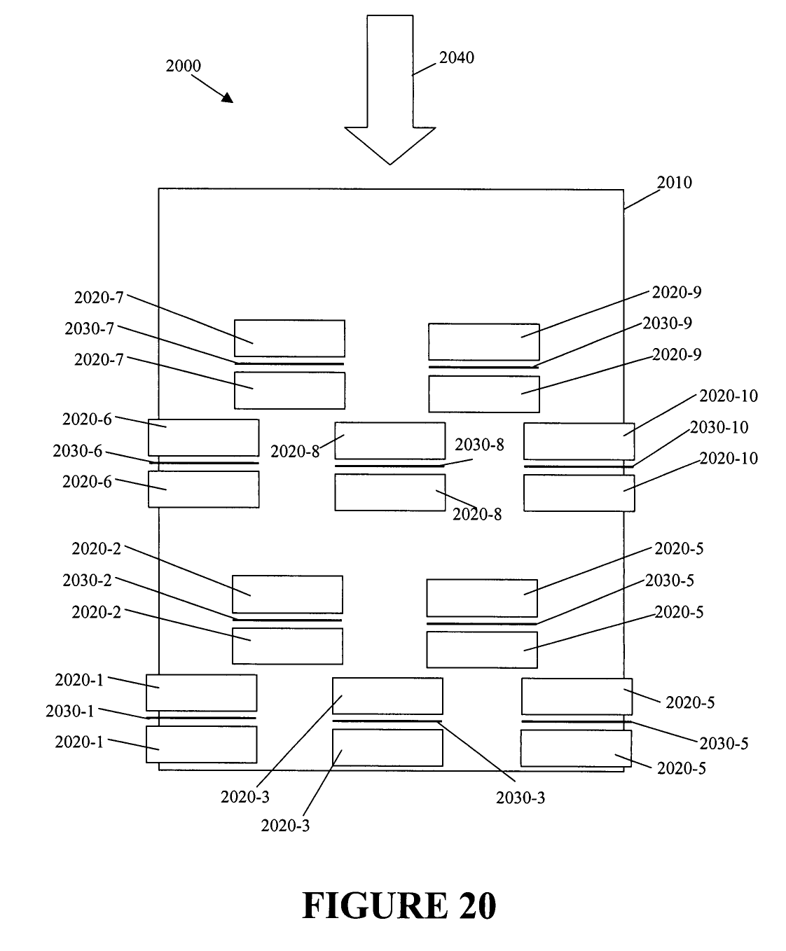

In another embodiment, FIG. 20 illustrates a top view of a schematic diagram of system 2000 in which a plurality of offset sources of focused or directed beams of energy are used to scan a large area substrate 2010 including one or more PV cells 100 in accordance with an embodiment of the presently described invention. While the discussion here focuses on e-beams, lasers and laser sources can be utilized in place of e-beams and e-beam sources in accordance with one or more embodiments of the presently described invention. Also, while the discussion here also focuses on the length of an emitted e-beam line, the discussion applies equally well to the width of a rastered e-beam point.

System 2000 includes a plurality of e-beam sources spatially offset from one another. In an embodiment, each source is a Pierce reflector that includes a plurality of reflectors 2020 and a filament 2030. In alternative embodiments, each source includes a point source e-beam that is focused using magnetic fields. While the e-beam sources in system 2000 are illustrated as comprising a Pierce reflector that includes a plurality of reflectors 2020 and a filament 2030, other e-beam sources are contemplated and encompassed in one or more embodiments of the presently described invention.

Similar to FIGS. 18 and 19, in FIG. 20 the reference number for each of the reflectors and filament includes an additional number such as −1, −2, −3, −4 or −5, up through −10. This additional number is used to clarify to which reflector 2020 and filament 2030 set is referred in this discussion.

Similar to substrates 1810 and 1910, substrate 2010 can be embodied in one or more cells 100 described herein. That is, substrate 2010 can include one or more cells 100 that each include semiconductor layer 150. Substrate 2010 preferably is of sufficient size or area that a single e-beam source cannot emit an e-beam so as to cover all of substrate 2010 or all of a width of substrate 2010 at once. That is, substrate 2010 is preferably wider than the width of a line e-beam or the raster pattern of a point-e-beam emitted by each e-beam source. For example, each e-beam line emitted by each e-beam source can be limited to a width (or length of the line) that is on the order of 2 and 10 cm. However, substrates that can be used in accordance with one or more embodiments of the presently described invention can be considerably wider than 2 to 10 cm. For example, if the length of a line e-beam is 2 to 10 cm, then substrate 2010 can have a width that is greater than 10 cm and/or a total area that is greater than 1 m².

In another example, the length of a line e-beam can be a fraction of the width of substrate 2010. For example, each line e-beam can have a length that is approximately one-fifth, one-quarter, one-third or one-fourth of the width of substrate 2010. Again, by “approximately,” it is meant that a line e-beam is emitted using available e-beam devices, systems and apparatuses with the intention of emitting a line beam of a particular length, but due to slight variances in this length that are caused by the device, system or apparatus employed, the intended beam length varies. For example, a variance of +10% of the intended line e-beam length can be acceptable. However, a smaller variance also is within the scope of one or more embodiments of the presently described invention.

In order to cover a large-area substrate 2010, the sets and each of the plurality of e-beam sources in each set can be spatially offset from one another. As shown in FIG. 20, the two sets of e-beam sources are offset from one another and each source in each set is offset from one another in two directions in a plane parallel to substrate 2010. With respect to the page of FIG. 20, the e-beam sources are offset in a left/right direction and an up/down direction of the page. In such a configuration, the total e-beams produced by the sources can cover a larger area, if not all, of a width of substrate 2010. System 2000 is similar to system 1800, with the addition of a second set of filaments 2030 and reflectors 2020. That is, while system 1800 includes a single set of filaments 1830-1, 1830-2, 1830-3, 1830-4 and 1830-5 and reflectors 1820-1, 1820-2, 1820-3, 1820-4 and 1820-5, system 2000 includes two sets of filaments 2030 and reflectors 2020. The first set includes filaments 2030-1, 2030-2, 2030-3, 2030-4 and 2030-5 and reflectors 2020-1, 2020-2, 2020-3, 2020-4 and 2020-5. The second set includes filaments 2030-6, 2030-7, 2030-8, 2030-9 and 2030-10 and reflectors 2020-6, 2020-7, 2020-8, 2020-9 and 2020-10.

With the additional set of filaments 2030 and reflectors 2020, a desired area of substrate 2010 or all of substrate 2010 can be exposed to e-beams in less time that is required for system 1800. That is, while system 2000 operates in a manner similar to system 1800 of FIG. 18, with the addition of multiple rows of e-beams produced by multiple offset e-beam sources. System 2000 can be more advantageous over system 1800 when relatively low scan speeds are used.

In system 2000, substrate 2010 can move relative to the e-beam sources in the direction indicated by arrow 2040. In another embodiment, substrate 2010 can move in a direction opposite that, or different from the direction indicated by arrow 2040. In another embodiment, the e-beam sources move relative to substrate 2010, which remains stationary. In such an embodiment, the e-beam sources can move in the direction indicated by arrow 2040, in a direction opposite that of arrow 340 or in another direction different from arrow 2040.

In an embodiment of the presently described invention, systems 1800, 1900 and 2000 include a conveyor or other mechanical devices for moving substrate 1810, 1910, 2010 and/or the e-beam sources relative to one another. In addition, an aperture can be placed between one or more e-beam sources and substrate 1810, 1910, 2010 to reduce or minimize any overlap of e-beams produced by adjacent e-beam sources.

Embodiments of the presently described invention illustrated in and described with respect to FIGS. 18 through 20 provide several advantages over existing systems and methods. For example, much greater uniformity in the level of crystallinity of semiconductor layer 150 can be obtained by using several identical or similar electron beams to expose layer 150 rather than a single electron beam that spans the entire substrate. For example, existing line- or point-source electron beams cannot maintain their uniformity indefinitely in a direction perpendicular to the scan direction. Therefore, in order to obtain highly uniform large-area semiconductor films and achieve high throughput, one or more embodiments of the presently described invention use a plurality of e-beams and e-beam sources instead of one. In addition, for a given scan speed, the time needed to process an entire substrate 1810, 1910, 2010 is reduced by a factor of n when n electron beams are used instead of one.

While certain systems and methods for exposing cell(s) 100 and substrates including cell 100 are described above, these are only examples of how cell 100 can be exposed to e-beams. Other e-beam systems and/or heating systems can be employed to increase the level of crystallinity in semiconductor layer 150. For example, a greater or smaller number of filaments and reflectors can be used. In another example, instead of or in addition to exposing cell 100 to e-beams in order to heat layer 150 at or near its melting temperature, heat can be applied to layer 150 by a heating element located beneath substrate 110. Heat then travels through substrate 110, barrier layer 120, layer 130 and passivation layer 140 (if applicable) to layer 150 in order to heat layer 150.

In another example, one or more e-beam sources can be housed in a chamber separate from the chamber that includes cell 100 and layer 150. For example, the filaments of an e-beam source can be housed in a second vacuum chamber that maintains a lower base pressure near the filament (for example, less than 10⁻⁴ to 10⁻⁸ torr). The chamber housing cell 100 and layer 150 can be maintained at a higher pressure than the second chamber (for example, 10⁰ to 10⁻⁶ torr). The two chambers can be connected by a narrow slit through which e-beams emitted by the filament in the second chamber passes. In some cases, the slit can be covered by a thin piece of material that is penetrable by the emitted e-beam. The advantage of this approach is that the time required to pump down the chamber the houses cell 100 and layer 150 can be reduced while increasing the overall stability of the e-beam.

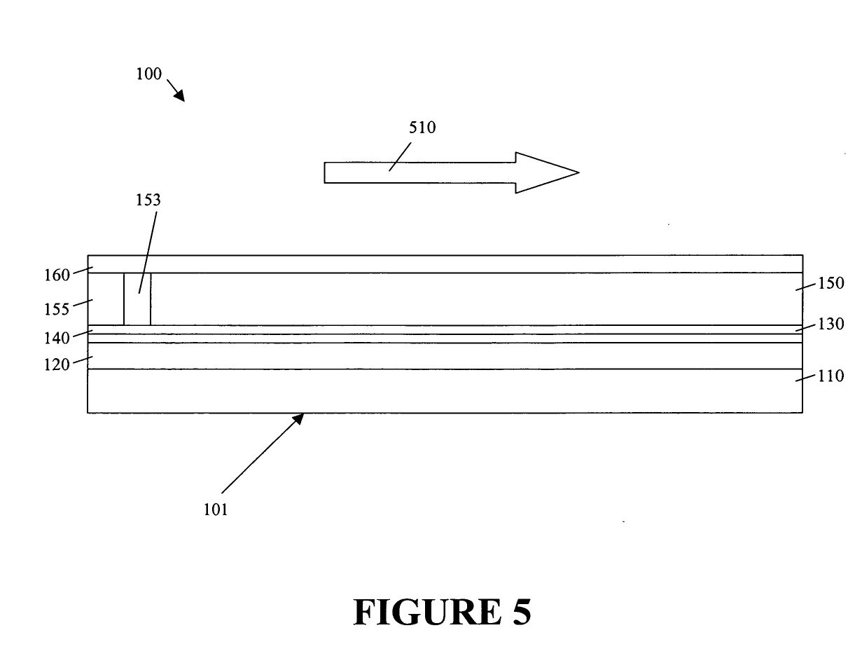

In an embodiment, the e-beams are emitted by the e-beam sources described above so that semiconductor layer 150 crystallizes (or increases the level of crystallinity of layer 150). FIGS. 5 through 8 illustrate cross-sectional views of cell 100 at another step in a method of fabricating the module in accordance with an embodiment of the presently described invention. In FIGS. 5 through 7, the initial semiconductor layer 150 is melted, or brought to a temperature at or near its melting temperature, thus causing a heated portion 153 of layer 150 to be created. As the emitted e-beams or laser beams move relative to the substrate that includes cell 100 (as described above), portion 153 moves in the same direction as the relative movement indicated by arrow 510. As portion 153 moves, the portion of layer 150 that previously was heated and/or melted begins to cool and crystallize, or at least increase the level of crystallinity in layer 150. Once layer 150 has been heated and cooled, a crystallized portion of layer 150, or crystallized layer 155, is created. By “crystallized layer,” it is meant that the level of crystallinity in layer 155 has been increased to be greater than the level of crystallinity in the remainder of layer 150.

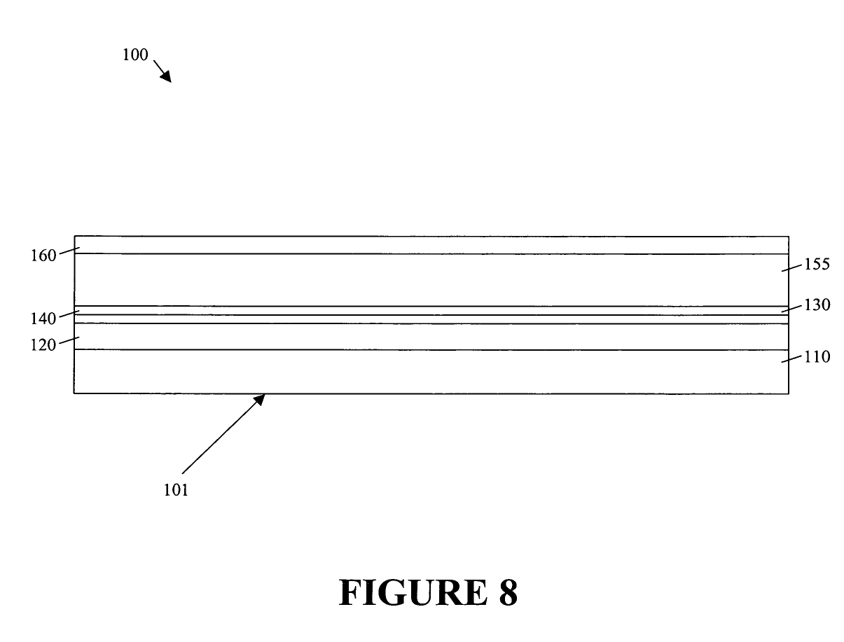

As the e-beams or laser beams move relative to cell 100, portion 153 moves in the same direction, crystallized layer 155 increases along this same direction, and the non-crystallized portion of layer 150 (that is, the layer that has a smaller level of crystallinity than portion 155) becomes smaller, as shown in FIGS. 5 through 7. Once portion 153 has passed through the entirety of cell 100, all or substantially all of layer 150 becomes crystallized layer 155, as shown in FIG. 8. That is, the level of crystallinity of layer 150 is increased.

In an embodiment, layer 150 is melted only a single time to increase its level of crystallinity. In an alternative embodiment, layer 150 can be exposed to the e-beams or laser beams multiple times in an effort to further heat and increase the level of crystallinity of layer 150.

As described above, semiconductor layer 150 can be heated at or near its melting temperature to increase its level of crystallinity and create crystallized layer 155. For example, where silicon is used as layer 150, layer 150 can be heated to 1100-1500° C. Of course, different temperatures can be used for different materials in layer 150, and different temperatures can be used if layer 150 is not to be heated. That is, if the crystallization of layer 150 is done in the solid-state.

In another embodiment of the presently described invention, a level of crystallinity of layer 150 is increased by raising the temperature of layer 150 to a point below the melting temperature of the material or materials in layer 150. That is, at step 1716 the crystallinity of layer 150 is increased by exposing cell 100 and layer 150 to one or more directed or focused beams of energy without melting layer 150 and while maintaining layer 150 in a solid state. For example, layer 150 can be crystallized by exposing it to e-beams or lasers while keeping the temperature of layer 150 below its melting temperature.

The settings for the e-beam sources used to increase the crystallinity of layer 150 can be varied based on several factors, including the desired heating temperature, the thickness of layer 150, the thickness of additional layers located between layer 150 and the e-beam or laser sources (through which the emitted e-beams or lasers must penetrate), and the desired speed at which layer 150 is heated. For example, by varying the voltage supplied to e-beam sources, the depth of penetration of the emitted e-beams into cell 100 can vary. As the voltage is increased, the emitted e-beams can penetrate deeper into cell 100. Thus, where a relatively thick layer 150 is utilized and/or relatively thick layers between layer 150 and the e-beam sources are used, a higher voltage can be necessary to achieve the desired level of crystallinity in layer 150 and/or the desired speed at which step 1716 is completed. In another example, by varying the current supplied to the e-beam sources, the power of the e-beams, and therefore the rate at which layer 150 is heated and the temperature to which layer 150 is heated, varies. As the current is increased, the layer 150 can heat at a greater rate and/or to a greater temperature.

As described above, in one or more embodiments passivation layer 140 and/or capping layer 160 can be intentionally doped with p- or n-type dopants. In such embodiments, during the heating and subsequent cooling of cell 100 at step 1716, one or more of these dopants can diffuse from layer 140 and/or layer 160 into semiconductor layer 150. As a result, the concentration of the dopants supplied by layer 140 and/or layer 160 can increase locally in semiconductor layer 150 or layer 155.

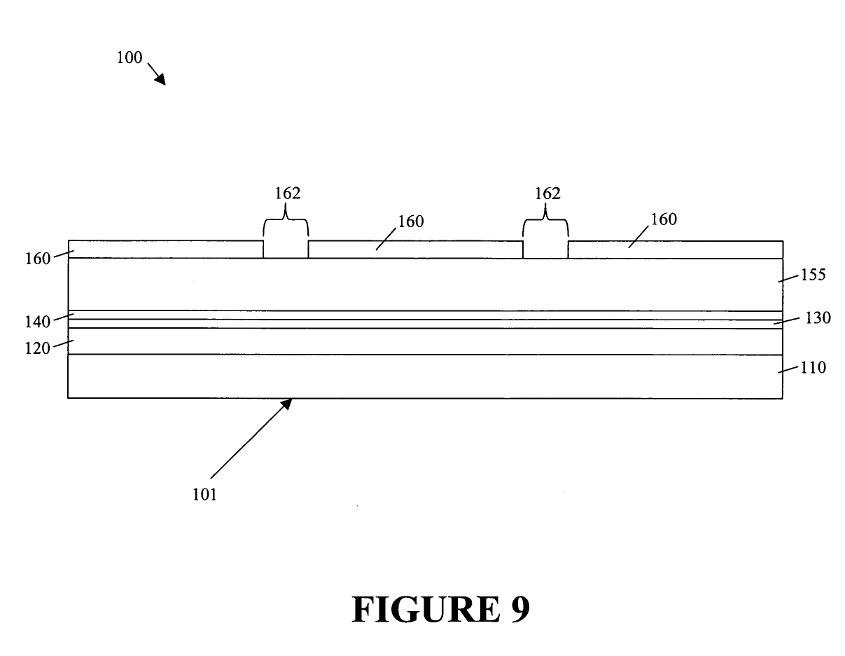

Once the desired level of crystallinity is obtained at step 1716, method 1700 proceeds to step 1718. At step 1718, capping layer 160 is etched in a pattern. For example, standard photolithography tools and systems can be employed to create a desired pattern in capping layer 160. A wet or dry etching process can then be used to remove desired portions of layer 160, as illustrated in FIG. 9. The capping layer 160 can be etched to provide a first set of openings 162 in layer 160 to crystalline layer 155 so that corresponding areas of layer 155 are exposed. These first exposed areas can then be doped with p- or n-type dopants, as described below.

In an embodiment where no capping layer 160 is utilized, a layer can be deposited following step 1716 to act as a masking layer for the doping step. For example, an insulating layer (such as SiO₂) can be deposited adjacent to layer 155 (similar to layer 160) after step 1716. This insulating layer can then be patterned and etched to remove a first set of areas of the insulating layer. Similar to capping layer 160, this etching also exposes a first set of areas of layer 155 for later doping.

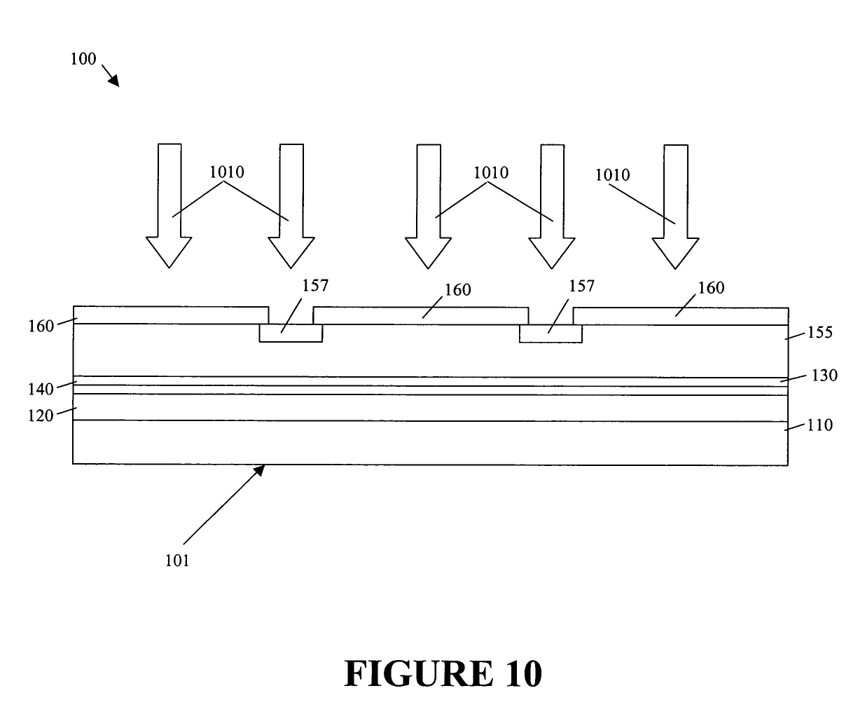

Next at step 1720, crystalline layer 155 is doped with an n- or p-type dopant on a side of cell 100 opposite side 101, as illustrated in FIG. 10. For example, in the embodiment where passivation layer 140 and layer 155 are doped with p-type dopants and capping layer 160 is doped with an n-type dopant, layer 155 can be doped at step 1720 with a p-type dopant. In an embodiment, layer 155 is doped at step 1720 using ion implantation or an ion shower to create doped volumes or portions 157. The general direction of ion implantation at step 1720 is illustrated by arrows 1010 in FIG. 10. However, other doping techniques or methods can also be used. As shown in FIG. 10, the sections of capping layer 160 that were not etched away at step 1718 can prevent or impede the doping of layer 155 adjacent to or beneath capping layer 160. In one embodiment, these doped volumes 157 can include a dopant concentration that is on the same order of magnitude as passivation layer 140. However, volumes 157 and 159 can include a greater or lesser dopant concentration relative to passivation layer 140.

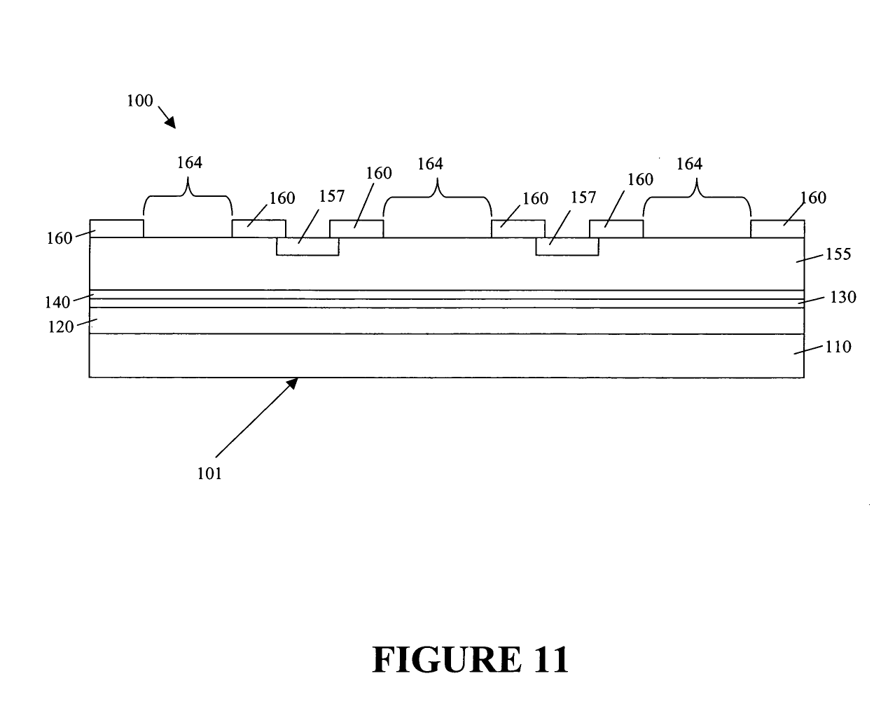

Once the desired volume of and/or dopant concentration in doped volumes 157 are obtained, method 1700 proceeds to step 1722. At step 1722, capping layer 160 is again etched in a pattern. For example, standard photolithography tools and systems can be employed to create a pattern in the remaining portions of capping layer 160. A wet or dry etching process can then be used to remove remaining desired portions of layer 160, as illustrated in FIG. 11. Capping layer 160 can be etched to provide additional openings 164 in layer 160 to layer 155 so that corresponding volumes of layer 155 can later be doped with p- or n-type dopants, as described below.

In an embodiment where no capping layer 160 is utilized in cell 100, the remainder of an insulating layer that is deposited and etched in a manner similar to layer 160 (as described above) is removed. A second insulating layer (such as SiO₂, for example) can then be deposited similar to capping layer 160. This second layer can then be patterned and etched to remove a second set of areas of the insulating layer. By removing these areas, a second set of areas of layer 155 can be exposed. At this point, volumes of layer 155 corresponding to this second set of exposed areas can be doped with p- or n-type dopants, as described below.

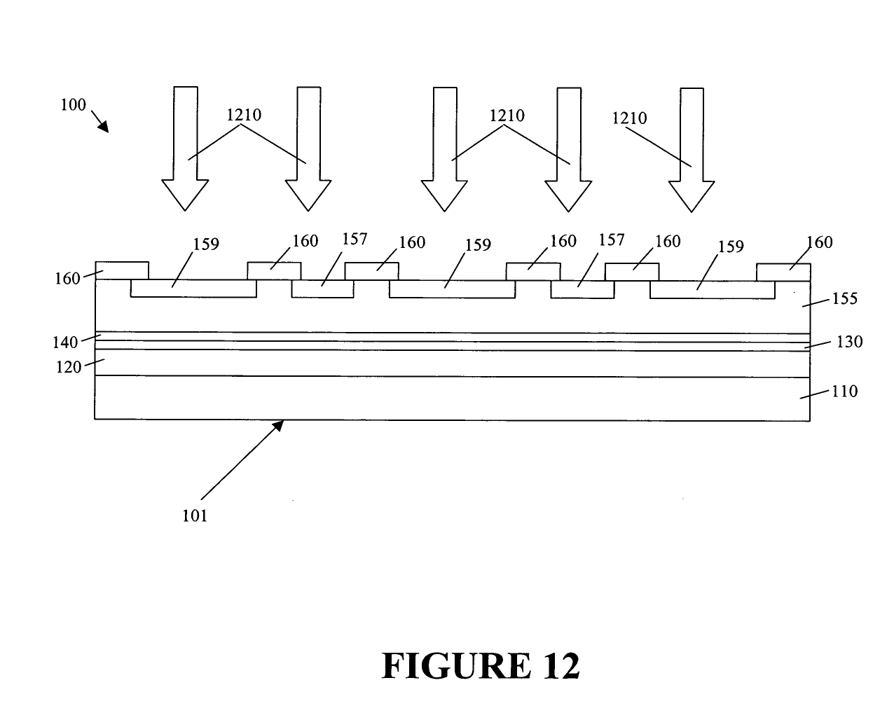

Next at step 1724, crystalline layer 155 is again doped with an n- or p-type dopant on the same side as layer 155 was doped at step 1720, as illustrated in FIG. 12. For example, in the embodiment where passivation layer 140, layer 155 and doped volumes 157 are doped with p-type dopants and capping layer 160 is doped with an n-type dopant, layer 155 can be doped at step 1724 with an n-type dopant. In an embodiment, layer 155 is doped at step 1724 using ion implantation or an ion shower to create second doped volumes or portions 159. The direction of ion implantation at step 1724 is illustrated by arrows 1210 in FIG. 12. However, other doping techniques or methods can also be used.

As shown in FIG. 12, the sections of capping layer 160 that were not etched away at steps 1718 and 1722 can prevent or impede the doping of layer 155 adjacent to or beneath the remaining portions of capping layer 160. In one embodiment, these doped volumes 159 can include a dopant concentration that is on the same order of magnitude as passivation layer 140 and/or capping layer 160. However, other dopant concentrations are within the scope of one or more embodiments of the presently described invention. In another embodiment, the dopant concentration in volumes 159 is selected to be different or less than that of volumes 157 so as to avoid compensating for the dopant in volumes 157. For example, if volumes 157 have a p-type dopant concentration of 10²⁰/cm³ , the n-type dopant concentration in volumes 159 can be less than 5×10¹⁹/cm³ to reduce or avoid compensating for or canceling the dopants in volumes 157.

In an embodiment where no capping layer 160 is utilized but one or more insulating layers are used to control which areas and volumes of layer 155 are exposed and doped, the remaining portion of the insulating layer can be removed after step 1724.

In an embodiment of the presently described invention, doped volumes 157 and/or 159 penetrate into crystalline semiconductor layer 155 a depth that is less than the thickness of barrier layer 120 and/or capping layer 160. In addition, doped volumes 157 and/or 159 penetrate into crystalline semiconductor layer 155 a depth that is greater than the thickness of layer 120 or passivation layer 140. For example, volumes 157 and/or 159 can penetrate into layer 155 at a depth that is less than or equal to 100 nm, or 100×10⁻⁹ m. In another embodiment, volumes 157 and/or 159 can penetrate into layer 155 at a depth that is approximately 10 to 1000 nm, or 10×10⁻⁹ to 1000×10⁻⁹ m. By “approximately” with respect to the depth of volumes 157 and 159, it is meant that layer 155 is doped using available devices, systems and apparatuses with the intention of doping layer 155 to an intended depth, but due to slight variances in this depth that are caused by the device, system or apparatus employed, the intended depth varies. For example, a variance of +50% of the intended dopant depth of volumes 157 and 159 can be acceptable. However, a smaller variance also is within the scope of one or more embodiments of the presently described invention. In addition, the depth of volumes 157 and/or 159 can vary from the above and still fall within the scope of one or more embodiments of the presently described invention.

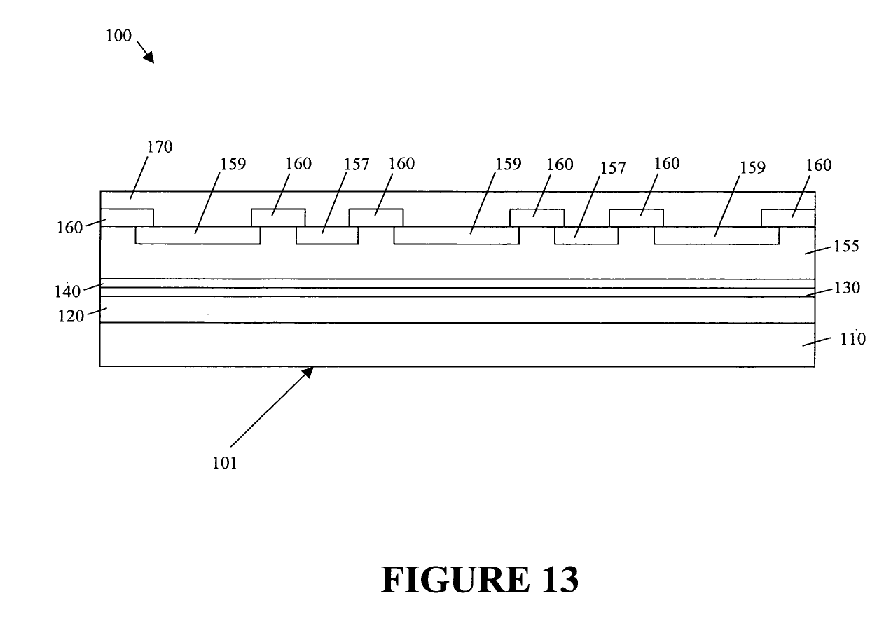

Next, at step 1726, a layer of conductive material 170 is deposited adjacent to capping layer 160 (if layer 160 is utilized) and volumes 157, 159 of layer 155, as shown in FIG. 13. If no layer 160 is utilized, layer 170 is deposited adjacent to exposed regions of layer 155 and volumes 157 and 159, or to volumes 157 and 159 and any remaining masking material. The side of cell 100 that layer 170 is deposited can be referred to as the electrode side or surface of cell 100. The electrode or surface side of cell 100 is opposite the side that incident light strikes (that is, side 101 of cell 100). For example, a metal such as aluminum can be sputtered adjacent to capping layer 160 and volumes 157, 159 of layer 155. In an embodiment, layer 170 is opaque. That is, layer 170 is not transparent or translucent to incident light in such an embodiment. In another embodiment, layer 170 is non-opaque. That is, layer 170 is at least partially transparent or translucent to incident light.

The thickness of conductive material layer 170 should be sufficient to form conducting contacts with doped regions 157 and 159, or surface areas of layer 155 that correspond to volumes 157, 159 of layer 155. Preferably, the thickness should be sufficient to form highly conductive contacts with surface areas corresponding to volumes 157 and 159. For example, layer 170 can be deposited to be 100 to 1000 nm (100×10⁻⁹ to 1000×10⁻⁹ m) thick where layer 170 comprises aluminum.

Conductive layer 170 can be used to provide electrical contacts to doped volumes 157 and 159 of layer 155 on the same side of cell 100. As the electrical contacts are located on one side of cell 100, an all-back contact device can be created, as described above. In addition, because little to no light passes through these top electrical contacts, the contacts can be made thicker, or as thick as necessary to reduce or essentially eliminate series resistance losses in the contacts with regions 157 and 159.

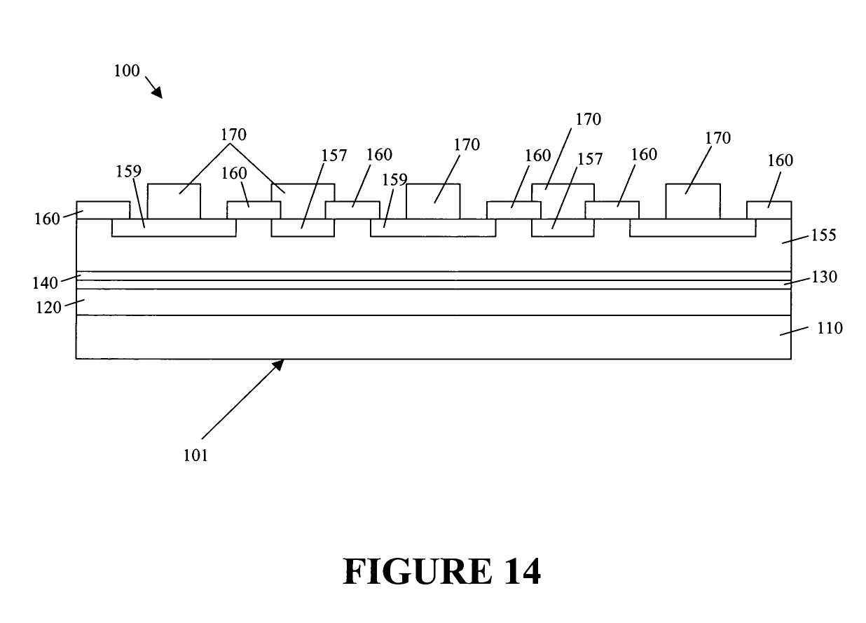

Next, at step 1728, conductive layer 170 is etched in a pattern. For example, standard photolithography tools and systems can be employed to create a pattern in conductive layer 170. A wet or dry etching process can then be used to remove remaining desired portions of conductive layer 170, as illustrated in FIG. 14. While a relative width of the remaining portions of conductive layer 170 is shown in FIG. 14, these remaining portions can be wider or narrower with respect to capping layer 160 and/or doped volumes 157 and 159. These remaining portions can act as electrical contacts to the doped regions of cell 100. In an embodiment, the mean, median or majority of distances between adjacent electrical contacts that are formed by etching layer 170 is less than the thickness of layer 150 or 155.

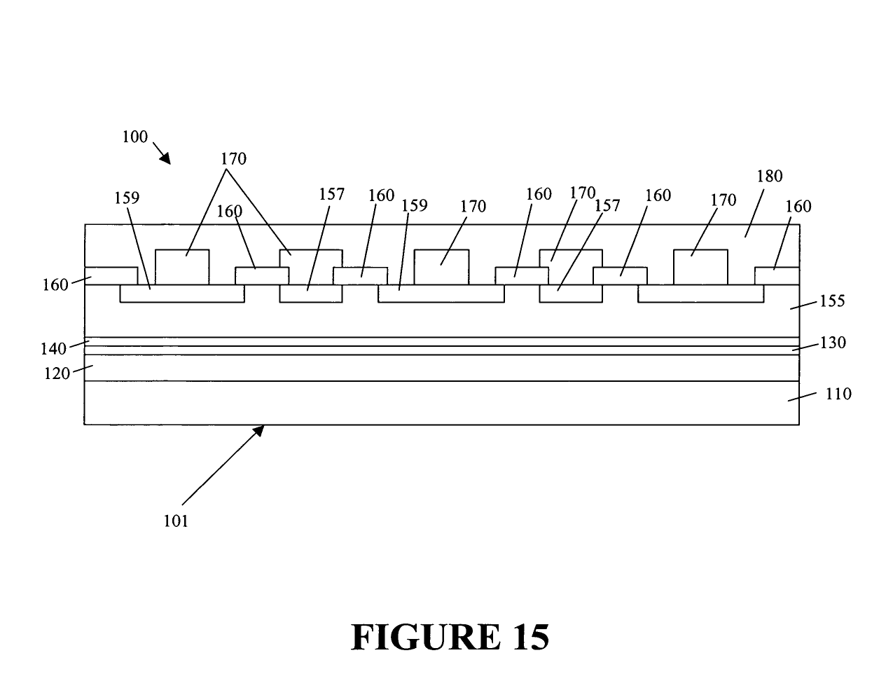

After step 1728, method 1700 proceeds to step 1730. At step 1730, a layer of light scattering material 180 is deposited adjacent to capping layer 160, the remaining portions of conductive layer 170 and/or volumes 157, 159 of layer 155, as shown in FIG. 15. The material in light scattering layer 180 can comprise a material that scatters light. For example, layer 180 can comprise nanoparticles of silicon dioxide (SiO₂), titanium dioxide (TiO₂) or zinc oxide (ZnO).

In an embodiment, layer 180 is deposited using screen printing or inkjet printing. Light scattering layer 180 can be deposited in a thickness of 1 to 5 μm, or 1×10×10⁻⁶ to 5×10⁻⁶ m, for example.

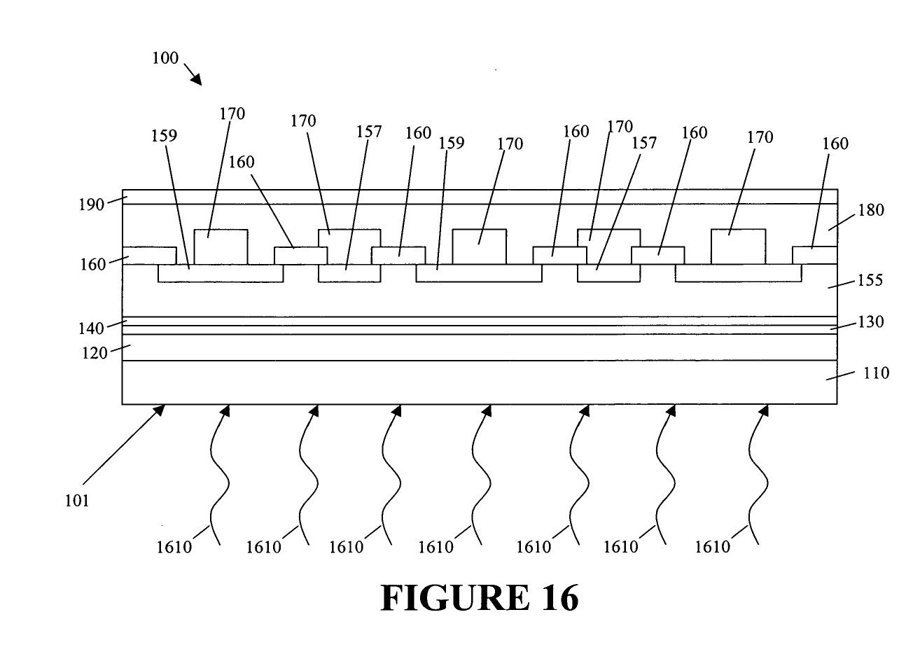

After step 1730, method 1700 proceeds to step 1732, where an encapsulation layer 190 is deposited adjacent to light scattering layer 180, as illustrated in FIG. 16. Encapsulation layer 190 can comprise a transparent or partially transparent nonconductive material such as Si₃N₄ or glass. In an embodiment, encapsulation layer 190 is deposited using PECVD or sputtering. Layer 190 can be deposited in a variety of thicknesses. For example, layer 190 can be deposited in a thickness of 500 nm to 2 μm (or 500×10⁻⁹ to 2×10⁻⁶ m), for example. In another embodiment, layer 190 includes a layer of glass that is bound to layer 180 by an adhesive. The layer of glass can include tempered glass, float glass or borosilicate class, for example.

In an embodiment, one or more of steps 1718 through 1732 is performed in a vacuum environment of 10⁰ to 10⁻⁶ torr, while other steps are performed outside of a vacuum environment. For example, in patterning and etching capping layer 160 or an insulating mask, one or more steps of photoresist deposition, photolithographic exposure, and rinsing can be performed in air or under atmospheric conditions. The actual etching of capping layer 160, the insulating mask or conductive layer 170 can be performed in air or under atmospheric conditions in an acid bath (that is, a wet etch). Alternatively, the etching can occur in a plasma environment (that is, a dry etch).

In another example, doping of layer 155 using ion implantation can be done in a vacuum. Depositing layer 170 can be performed using sputtering in a vacuum at a pressure of approximately 10⁻³ torr. Deposition of light scattering layer 180 can be performed in air using screen printing, for example. Encapsulation layer 190 can be deposited using PECVD in a vacuum environment or in air if a top glass cover sheet is adhered to layer 180, as described above.

Once step 1732 is completed, a photovoltaic cell 100 is completed in accordance with an embodiment of the presently described invention, and is illustrated in FIG. 16. In operation, incident light 1610 (as shown in FIG. 16) strikes side 101 of cell 100 and passes through substrate 110, barrier layer 120, layer 130 and passivation layer 140 (if included) to strike semiconductor layer 155. The electricity thereby generated flows to the contacts formed by layer 170 in contact with regions 157 and 159. As no contacts formed by layer 170 are on side 101 of cell 100 in an embodiment, the efficiency of cell 100 can be greater than existing cells that include contacts on a side of the cell that incident light strikes.

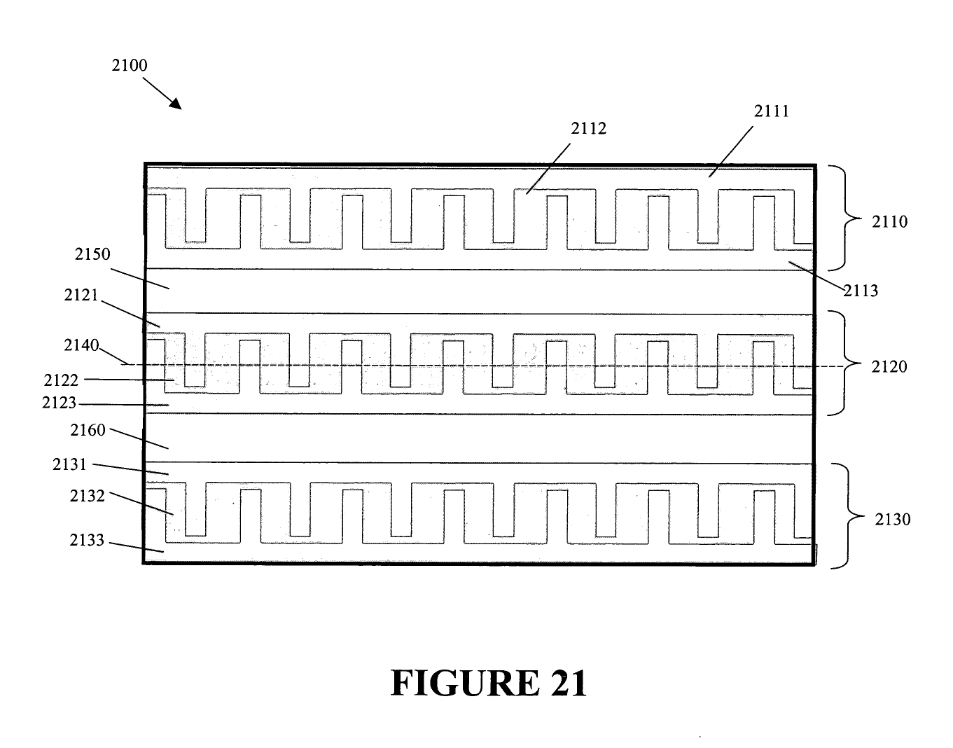

In addition to creating an all-back contact PV cell 100, one or more embodiments of the presently described invention provide a method for fabricating an all-back contact PV module 2100. Module 2100 includes a plurality of series-connected PV cells 100. FIG. 21 illustrates a schematic diagram of an all-back contact PV module 2100 with contacts 2150, 2160 between cells 2110, 2120 and 2130 in accordance with an embodiment of the presently described invention. The side of module 2100 that is illustrated in FIG. 21 can be referred to as the electrode side or surface of module 2100 and cells 2110, 2120 and 2130. This electrode side or surface is opposite the side of module 2100 and cells 2110, 2120 and 2130 that incident light strikes to generate electricity module 2100 and cells 2110, 2120 and 2130 (referred to as side 101 in FIG. 16).

Module 2100 includes a plurality of PV cells 2110, 2120 and 2130 and a plurality of interconnections or contacts 2150 and 2160 between cells 2110, 2120 and 2130. Line 2140 in FIG. 21 represents a section line indicating the location of the cross section of cell 100 illustrated in FIG. 16.

Each of cells 2110, 2120 and 2130 comprises first, second and third regions. For example, cell 2110 includes first region 2111, second region 2112 and third region 2113; cell 2120 includes first region 2121, second region 2122 and third region 2123; and cell 2130 includes first region 2131, second region 2132 and third region 2133.

In an embodiment, first regions 2111, 2121 and 2131 correspond to an area of cell 100 that includes a contact between one or more of doped regions 157 and contacts 170, as illustrated in FIG. 16. For example, first regions 2111, 2121 and 2131 can correspond to an area of cell 100 that includes a contact between one or more of regions 157 doped with a p-type dopant and aluminum contacts 170.

Second regions 2112, 2122 and 2132 include regions of crystalline semiconductor layer 155 that are not intentionally doped as are regions 157 and 159 during steps 1720 and 1724 in method 1700 and that are not covered by contacts 170. For example, where layer 155 is doped with a p-type dopants, second regions 2112, 2122 and 2132 include exposed crystalline semiconductor doped with a p-type dopant. Regions 2112, 2122 and 2132 can be formed by removing additional portions of capping layer 160 or an insulating mask (if no capping layer 160 is utilized) after step 1724 and before step 1726 in method 1700.

Third regions 2113, 2123 and 2133 correspond to an area of cell 100 that includes a contact between regions 159 and contacts 170, as illustrated in FIG. 16. For example, third regions 2113, 2123 and 2133 can correspond to an area of cell 100 that includes a contact between one or more regions 159 doped with an n-type dopant and aluminum contacts 170.

Cells 2110, 2120 and 2130 can be electrically isolated from one another by scribing or etching a line 2150 or 2160 between cells 2110, 2120, and 2130. This isolation of cells 2110, 2120 and 2130 can occur by patterning and etching layer 155 after doping layer 155 with the second type of dopant (that is, after step 1724) and before providing conductive layer 170 (that is, before step 1726). In such an embodiment, layer 155 can be etched completely through or through substantially all of layer 155 to form gaps located at lines 2150 and 2160. Before step 1726, an insulator material can be deposited in the volume of cells 2110, 2120 and 2130 where layer 155 was completely or substantially removed. This insulator material can help to prevent or avoid electrical “cross-talk” between two or more of cells 2110, 2120 and 2130 once conductive layer 170 is deposited. That is, the insulator material can prevent electrically shorting two adjacent cells 2110, 2120 and 2130 in module 2100. The insulator material can comprise silicon dioxide (SiO₂), for example. Another example of an insulator material is a polyimide. The insulator material can be deposited using a sol-gel deposition technique, for example.

Once conductive layer 170 is deposited at step 1726 and after etching layer 155 and depositing an insulator in the gap left by the removed portions of layer 155, layer 170 can be selectively etched at step 1728 so as to electrically connect a first region 2111, 2121 or 2131 of one cell 2110, 2120 or 2130 with a third region 2113, 2123 and 2133 of another cell 2110, 2120 or 2130. Once created, contacts 2150 and 2160 connect a third region in one cell 2110, 2120 or 2130 with a first region in another cell 2110, 2120 or 2130. For example, as illustrated in FIG. 21, contact 2150 connects third region 2113 with first contact 2121 and contact 2160 connects third region 2123 with first region 2131. For example, layer 170 can be etched to connect a n-type doped region of one cell with the p-type doped region of an adjacent cell. By etching layer 170 in this manner, conductive contacts are established to bridge the etched gaps in layer 155 (and later filled with an insulator material, in an embodiment of the presently described invention) to electrically connect one cell to another cell. These contacts are referred to as contacts 2150, 2160.

By connecting a p-type region of one cell to a n-type region of the next cell (for example, by etching layer 170 so as to electrically connect a first region 2111, 2121 or 2131 of one cell 2110, 2120 or 2130 with a third region 2113, 2123 and 2133 of another cell 2110, 2120 or 2130), adjacent cells can be electrically connected in a series. As a result, a PV module can be formed that sums the output voltages of individual cells 2110, 2120 or 2130 to generate a total module output voltage.

In accordance with one or more embodiments of the presently described invention, most, if not all of the needs in the art outlined above are met. First, embodiments of the presently described invention reduce the cost for manufacturing PV cells and modules. The expensive and time-consuming methods of manufacturing PV cells and modules using electronic-grade semiconductor wafers are avoided without sacrificing the quality of the semiconductor film in the PV cell or module. By depositing an amorphous or microcrystalline semiconductor film instead of utilizing a wafer to create a cell or module, the film can be deposited or established much more quickly and cheaply, and can dramatically reduce the amount of costly semiconductor material used in the cell or module.

Second, by utilizing a relatively thin semiconductor film and quickly or rapidly annealing the films using e-beams to increase the crystallinity of the film in accordance with an embodiment of the presently described invention, a cheaper substrate can be used when compared to existing systems in which substrates that are capable of withstanding high temperatures must be used. For example, in existing systems and methods, substrates such as quartz or fused silica needs to be used as these substrates can withstand the temperatures required for increasing the crystallinity in semiconductor layers. These temperatures can exceed 750-2000° C., which is considerably larger than the melting temperature of the various substrates that can be used in accordance with one or more embodiments of the presently described invention. Using one or more embodiments of the presently described invention, a lower cost substrate can be used as the substrate is less likely to be damaged by the temperatures required to increase the crystallinity of the semiconductor layer (that is, layer 155).

Third, by placing both the n- and p-type contacts on the top of the semiconductor film (that is, layer 155), potential damage to an underlying electrode layer during step 1716 is avoided. In addition, the top conductive layer (that is, layer 170) can be made thick enough to mitigate series resistance losses in the contacts. In contrast, in existing thin-film solar modules, one or more contacts are transparent and cannot be made arbitrarily thick without incurring parasitic absorption losses.

Finally, by utilizing an insulating substrate (that is, substrate 110) to carry the semiconductor material (that is, layers 150 and 155), the process of making a PV module from a PV cell is greatly simplified because electrically interconnecting adjacent cells can be accomplished in the same step as the electrical contact definition. In contrast, in existing wafer-based modules, the contacts of adjacent wafers must be soldered together using an extra cumbersome manufacturing step.

While particular elements, embodiments and applications of the presently described invention have been shown and described, it is understood that the presently described invention is not limited thereto since modifications may be made by those skilled in the technology, particularly in light of the foregoing teaching. It is therefore contemplated by the appended claims to cover such modifications and incorporate those features that come within the spirit and scope of the presently described invention.

1. A method for fabricating an all-back contact photovoltaic cell, said method including:
depositing a semiconductor layer on a non-opaque substrate;
increasing a level of crystallinity of said semiconductor layer by exposing said semiconductor layer to a focused beam of energy;
doping said semiconductor layer with first and second dopants on a side of said semiconductor layer to create at least two doped regions in said semiconductor layer; and
providing electrical contacts to said doped regions by depositing a conductive layer on said side of said semiconductor layer so that said electrical contacts are on said side of said semiconductor layer and incident light strikes said semiconductor layer from an opposing side.

2. The method of claim 1, wherein said depositing step includes depositing said semiconductor layer in at least one of an amorphous state and a microcrystalline state.

3. The method of claim 1, wherein said increasing step includes melting at least a portion of said semiconductor layer.

4. The method of claim 3, wherein said increasing step includes melting at least said portion of said semiconductor layer with one or more electron beams.

5. The method of claim 1, wherein said substrate includes one or more materials having a softening point below 750° C.

6. The method of claim 1, further including depositing a barrier layer adjacent to said substrate and between said substrate and said semiconductor layer, said barrier layer impeding diffusion of one or more impurities from said substrate into said semiconductor layer during said increasing step.

7. The method of claim 1, further including depositing a passivation layer adjacent to said semiconductor layer and between said substrate and said semiconductor layer, said passivation layer electrically passivating a surface of said semiconductor layer.

8. The method of claim 1, further including:
depositing a capping layer adjacent to said side of said semiconductor layer;
etching said capping layer to expose a first set of areas of said semiconductor layer before doping said semiconductor layer with said first dopant;
etching said capping layer to expose a second set of areas of said semiconductor layer before doping said semiconductor layer with said second dopant, wherein said second set of areas include said first set of areas.

9. An all-back contact thin film photovoltaic cell including:
a non-opaque substrate;
a semiconductor layer deposited in at least one of an amorphous state and a microcrystalline state, wherein a level of crystallinity of said semiconductor layer is increased by exposing at least a portion of said semiconductor layer to one or more focused beams of energy;
a capping layer deposited adjacent to said semiconductor layer, said capping layer etched a first time to expose a first set of areas of said semiconductor layer and a second time to expose a second set of areas of said semiconductor layer, wherein said first set of areas is doped with a first type of dopant and said second set of areas is doped with a second type of dopant; and
a conductive layer deposited on a first side of said semiconductor layer opposite said substrate to provide electrical contacts with said first and second areas,
wherein incident light passes through said substrate and strikes said semiconductor layer on a second side that is opposite said first side.

10. The photovoltaic cell of claim 9, wherein said semiconductor layer is melted when exposed to said focused beams of energy.

11. The photovoltaic cell of claim 9, wherein said focused beams of energy include one or more electron beams.

12. The photovoltaic cell of claim 9, wherein said substrate includes one or more materials having a softening point below 750° C.

13. The photovoltaic cell of claim 9, further including a barrier layer deposited adjacent to said substrate and between said substrate and said semiconductor layer,
wherein said barrier layer impedes diffusion of one or more impurities from said substrate into said semiconductor layer.

14. The photovoltaic cell of claim 9, further including a passivation layer deposited adjacent to said semiconductor layer and between said substrate and said semiconductor layer, said passivation layer electrically passivating said second side of said semiconductor layer.

15. The photovoltaic cell of claim 9, wherein said second set of areas includes said first set of areas.

16. A method for fabricating an all-back contact photovoltaic module, said method including:
providing a semiconductor layer and a non-opaque substrate on a first side of said module;
increasing a level of crystallinity of said semiconductor layer by exposing said semiconductor layer to one or more focused beams of energy;
doping said semiconductor layer in each of a plurality of adjacent photovoltaic cells of said photovoltaic module with a first dopant in a first set of volumes in each of said photovoltaic cells;
doping said semiconductor layer with a second dopant in a second set of volumes in each of said photovoltaic cells;
removing a portion of said semiconductor layer to define a gap between said photovoltaic cells;
depositing an insulating material in said gap;
depositing a conductive material on said semiconductor layer at each of said first and second sets of volumes of each of said photovoltaic cells and on said insulating material; and
etching said conductive material to create electrical contacts (a) to said first set of volumes for each of said photovoltaic cells, (b) to said second set of volumes for each of said photovoltaic cells and (c) between said first set of volumes in one of said photovoltaic cells and said second set of volumes in another one of said photovoltaic cells,
wherein said electrical contacts are on a second side of said module that is opposite said first side and incident light passes through said substrate on said first side of said module and strikes said semiconductor layer.

17. The method of claim 16, wherein said providing step includes providing said semiconductor layer in at least one of an amorphous state and a microcrystalline state.

18. The method of claim 16, wherein said second set of volumes includes said first set of volumes in each of said photovoltaic cells.

19. The method of claim 18, wherein an amount of said second dopant that is deposited in said second set of volumes is less than an amount of said first dopant that is deposited at said first set of volumes for each of said photovoltaic cells.

20. The method of claim 16, wherein said substrate includes one or more materials having a softening point below 750° C.

21. An all-back contact photovoltaic module including:
a plurality of photovoltaic cells each including a semiconductor layer and a non-opaque substrate on a first side of said module, each of said semiconductor layers including a first set of volumes doped with a first dopant and a second set of volumes doped with a second dopant,
wherein a level of crystallinity of each of said semiconductor layers is increased by exposing said layers to one or more focused beams of energy;
an insulating material located in one or more gaps between adjacent ones of said photovoltaic cells, said gaps created by removing one or more portions of said semiconductor material in said module; and
a conductive material deposited adjacent to said first set of volumes and said second set of volumes for each of said cells and adjacent to said insulating material, said conductive material then etched to create electrical contacts (a) to said first set of volumes for each of said photovoltaic cells, (b) to said second set of volumes for each of said photovoltaic cells and (c) between said first set of volumes in one of said photovoltaic cells and said second set of volumes in another one of said photovoltaic cells;
wherein said electrical contacts are on a second side of said module that is opposite said first side and incident light passes through said substrate on said first side of said module and strikes said semiconductor layer.

22. The photovoltaic module of claim 21, wherein said semiconductor layer is initially deposited in at least one of an amorphous state and a microcrystalline state.

23. The photovoltaic module of claim 21, wherein said second set of volumes includes said first set of volumes in each of said photovoltaic modules.

24. The photovoltaic module of claim 23, wherein an amount of said second dopant that is deposited in said second set of volumes is less than an amount of said first dopant that is deposited in said first set of volumes for each of said photovoltaic cells.

25. The photovoltaic module of claim 23, wherein said substrate includes one or more materials having a softening point below 750° C.
